(19) United States
(12) Patent Application Publication
(10) Pub. No.: US 2026/0143259 A1
(43) Pub. Date: May 21, 2026

(54) PHOTOELECTRIC CONVERSION DEVICE AND PHOTOELECTRIC CONVERSION SYSTEM

(71) Applicant: CANON KABUSHIKI KAISHA, Tokyo (JP)

(72) Inventors: HIROTAKA SHUKURI, Tokyo (JP); NORIYUKI SHIKINA, Tokyo (JP); KAZUNORI MATSUYAMA, Kanagawa (JP); HIDETOSHI HAYASHI, Kanagawa (JP); SHINYA IGARASHI, Kanagawa (JP)

(21) Appl. No.: 19/382,549

(22) Filed: Nov. 7, 2025

(30) Foreign Application Priority Data
Nov. 15, 2024 (JP) 2024-199372

(51) Int. Cl. H04N 25/77; G06T 7/55; H04N 23/67; H04N 25/78; H10F 39/00

(52) U.S. Cl. CPC H04N 25/77; G06T 7/55; H04N 23/672; H04N 25/78; H10F 39/8063; G06T 2207/30261

(57) ABSTRACT

The photoelectric conversion device includes pixels including photoelectric conversion units and a charge holding portion, a control unit, and a signal processing unit. The pixels include in each row a first pixel transferring charges of first and second photoelectric conversion units according to first and second signals, respectively, and a second pixel transferring charges of first and second photoelectric conversion units according to the second and first signals, respectively. The control unit performs the first readout operation using the first signal and the second readout operation using the first and second signals for each row. The signal processing unit outputs a signal based on charge of the first photoelectric conversion unit and a signal based on charges of the first and second photoelectric conversion units of the first pixel and does not output a signal based on charge of the second photoelectric conversion unit of the second pixel.

### BACKGROUND

### Field of the Technology

The present disclosure relates to a photoelectric conversion device and a photoelectric conversion system.

### Description of the Related Art

International Publication No. WO2016/103478 discloses an imaging device that performs a focus detection using a pupil division system on an imaging plane. Further, Japanese Patent Laid-Open No. 2020-098968 discloses an imaging device configured to easily generate a phase difference signal by mixing pixels for reading one data and pixels for reading the other data of a photoelectric conversion unit divided into two.

However, in the imaging device described in Japanese Patent Laid-Open No. 2020-098968, the amount of data from the readout to the generation of the phase difference signal increases, and consequently, the circuit scale and the power consumption increase.

### SUMMARY

The present disclosure is directed to a technique for reducing the number of signals and the amount of signal processing in a photoelectric conversion device that performs a focus detection using a pupil division system on an imaging plane.

According to one disclosure of the present specification, there is provided a photoelectric conversion device including a pixel unit including a plurality of pixels arranged to form a plurality of rows and a plurality of columns, each of the plurality of pixels including a first photoelectric conversion unit and a second photoelectric conversion unit that share one microlens, a charge holding portion configured to hold charge transferred from the first photoelectric conversion unit and the second photoelectric conversion unit, and an output unit configured to output a signal according to an amount of charge held by the charge holding portion, a control unit configured to control a transfer of charge from first photoelectric conversion unit and the second photoelectric conversion unit to the charge holding portion in the plurality of pixels in unit of rows, and a signal processing unit configured to process signals output from the pixel unit, wherein the pixel unit includes, in each of the plurality of rows, a first pixel in which charge of the first photoelectric conversion unit is transferred to charge holding portion according to a first control signal and charge of the second photoelectric conversion unit is transferred to charge holding unit according to a second control signal, and a second pixel in which charge of the first photoelectric conversion unit is transferred to charge holding portion according to the second control signal and charge of the second photoelectric conversion unit is transferred to charge holding unit according to the first control signal, wherein the control unit is configured to perform, for each of the plurality of rows, a first readout operation of supplying the first control signal and not supplying the second control signal, and a second readout operation of supplying the first control signal and the second control signal, and wherein the signal processing unit is configured to output a first signal based on an amount of charge of the first photelectric conversion unit that is read out from the first pixel in accordance with the first readout operation and a second signal based on charges of the first photelectric conversion unit and the second photoelectric conversion unit that is read out from the first pixel in accordance with the second readout operation, and not to output a third signal based on an amount of charge of the second photoelectric conversion unit that is read out from the second pixel in accordance with the first readout operation.

Features of the present disclosure will become apparent from the following description of embodiments with reference to the attached drawings. The following description of embodiments is described by way of example.

### BRIEF DESCRIPTION OF THE DRAWINGS

FIG. 1 is a block diagram illustrating a schematic configuration of a photoelectric conversion device according to a first embodiment.

FIG. 2 is an equivalent circuit diagram illustrating a configuration example of a pixel of the photoelectric conversion device according to the first embodiment.

FIG. 3 is a plan view of a pixel of the photoelectric conversion device according to the first embodiment.

FIG. 4 is a circuit diagram illustrating a connection relationship between a pixel unit and an AD conversion unit in the photoelectric conversion device according to the first embodiment.

FIG. 5 is a timing chart illustrating a method of driving the photoelectric conversion device according to the first embodiment.

FIG. 6 is a block diagram illustrating a configuration example of a signal processing unit in a signal processing device according to the first embodiment.

FIG. 7 is a block diagram illustrating a schematic configuration of a photoelectric conversion device according to a second embodiment.

FIG. 8 is a block diagram illustrating a configuration example of a signal conversion unit in the photoelectric conversion device according to the second embodiment.

FIG. 9A and FIG. 9B are diagrams illustrating an operation of the signal conversion unit in the photoelectric conversion device according to the second embodiment.

FIG. 10 is a timing chart illustrating a method of driving the photoelectric conversion device according to the second embodiment.

FIG. 11 is a block diagram illustrating a configuration example of a signal processing unit in a signal processing device according to the second embodiment.

FIG. 12 is a block diagram illustrating a schematic configuration of a photoelectric conversion device according to a third embodiment.

FIG. 13 is a circuit diagram illustrating a connection relationship between a pixel unit and an AD conversion unit in the photoelectric conversion device according to the third embodiment.

FIG. 14 and FIG. 15 are diagrams illustrating an operation of the signal addition unit in the photoelectric conversion device according to the third embodiment.

FIG. 16 is a timing chart illustrating a method of driving the photoelectric conversion device according to the third embodiment.

FIG. 17 is a block diagram illustrating a configuration example of a signal processing unit in a signal processing device according to the third embodiment.

FIG. 18A and FIG. 18B are diagrams illustrating the operation of the signal processing unit in the signal processing device according to the third embodiment.

FIG. 19 is a timing chart illustrating another driving method of the photoelectric conversion device according to the third embodiment.

FIG. 20 is a block diagram illustrating a schematic configuration of a photoelectric conversion system according to a fourth embodiment.

FIG. 21A is a diagram illustrating a configuration example of a photoelectric conversion system according to a fifth embodiment.

FIG. 21B is a diagram illustrating a configuration example of a movable object according to the fifth embodiment.

FIG. 22 is a block diagram illustrating a schematic configuration of an equipment according to a sixth embodiment.

### DESCRIPTION OF THE EMBODIMENTS

Hereinafter, embodiments according to the present disclosure will be described with reference to the drawings. In each of the embodiments described below, a photoelectric conversion device for imaging purposes will be mainly described as an example of a semiconductor device. However, the embodiments are not limited to photoelectric conversion devices for imaging purposes and may be applied to other semiconductor devices. For example, other examples of the photoelectric conversion device include a ranging device (a device for distance measurement and the like using a focus detection or a time of flight (TOF)), and a photometric device (a device for measuring the amount of incident light).

In the following embodiments, connection between elements of a circuit may be described. In this case, even when another element is interposed between the elements of interest, the elements of interest are treated as being connected to each other unless otherwise specified. For example, an element A is connected to one node of a capacitor C having a plurality of nodes, and an element B is connected to the other node. Even in such a case, the element A and the element B are regarded as being connected to each other unless otherwise specified.

### First Embodiment

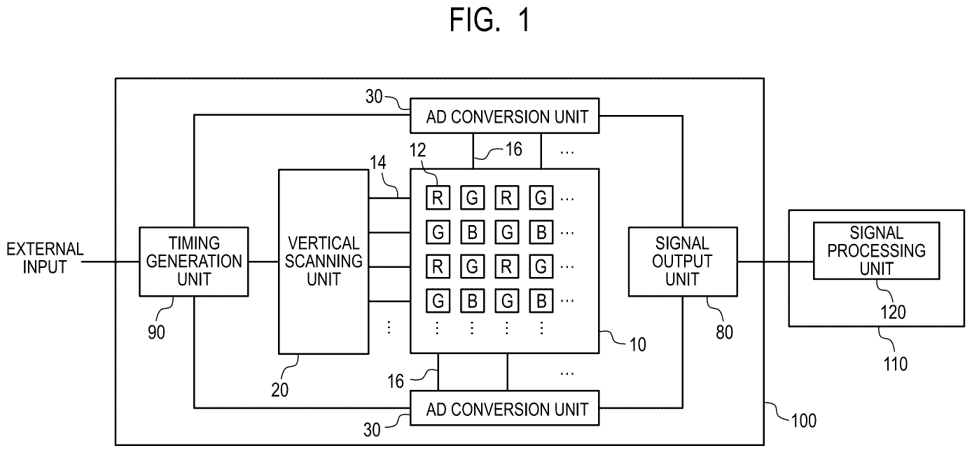

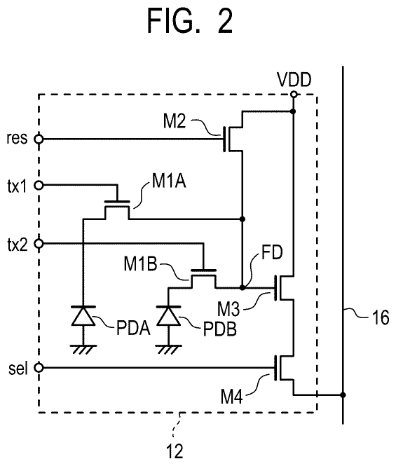

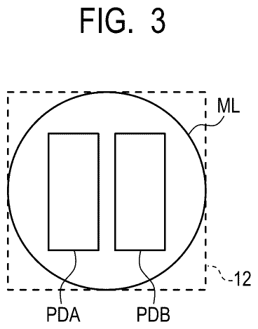

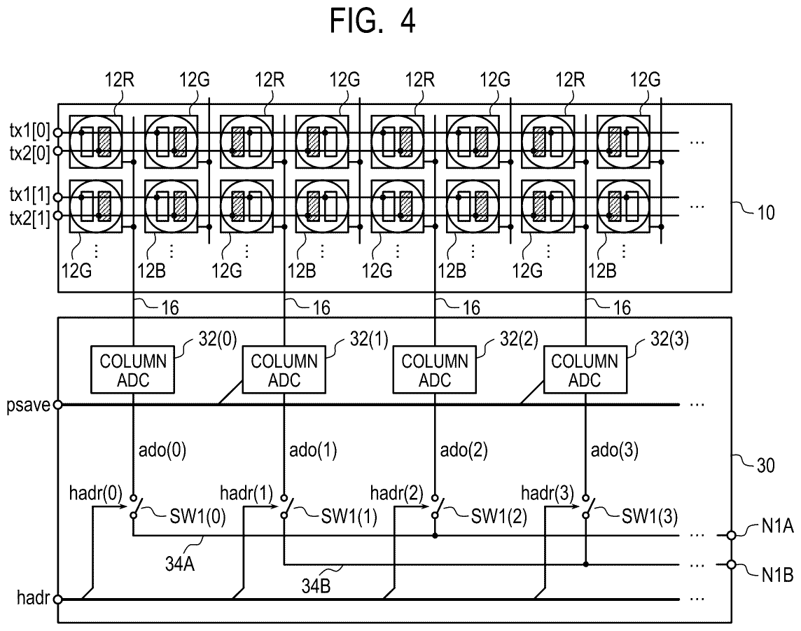

A photoelectric conversion device according to a first embodiment will be described with reference to FIG. 1 to FIG. 4. FIG. 1 is a block diagram illustrating a schematic configuration of a photoelectric conversion device according to the present embodiment. FIG. 2 is an equivalent circuit diagram illustrating a configuration example of a pixel of the photoelectric conversion device according to the present embodiment. FIG. 3 is a plan view of a pixel of the photoelectric conversion device according to the present embodiment. FIG. 4 is a circuit diagram illustrating a connection relationship between a pixel unit and an AD conversion unit in the photoelectric conversion device according to the present embodiment.

As illustrated in FIG. 1, the photoelectric conversion device 100 according to the present embodiment includes a pixel unit 10, a vertical scanning unit 20, an AD conversion unit 30, a signal output unit 80, and a timing generation unit 90. The pixel unit 10 is connected to the vertical scanning unit 20 and the AD conversion unit 30. The AD conversion unit 30 is connected to the signal output unit 80. The timing generation unit 90 is connected to the vertical scanning unit 20 and the AD conversion unit 30. The signal output unit 80 is connected to the signal processing unit 120. Note that the signal processing unit 120 may be provided in a signal processing device 110 different from the photoelectric conversion device 100 as illustrated in FIG. 1 or may be a part of the photoelectric conversion device 100. In this specification, functional blocks from the AD conversion unit 30 to the signal processing unit 120 may be collectively referred to as a signal processing unit.

The pixel unit 10 is provided with a plurality of pixels 12 two-dimensionally arranged in a plurality of rows and a plurality of columns. Each of the plurality of pixels 12 includes a photoelectric conversion unit and outputs a pixel signal according to the amount of incident light. Each pixel 12 includes one microlens and a color filter that transmits light in a predetermined wavelength range. In addition to an effective pixel that outputs a pixel signal according to the amount of incident light, an optical black pixel in which a photoelectric conversion unit is shielded, a dummy pixel that does not output a signal, or the like may be arranged in the pixel unit 10.

In FIG. 1, the color of the color filter included in each pixel 12 is represented by any symbol of R (Red), G (Green), or B (Blue). The pixel 12 marked with the symbol R is a pixel 12 provided with a red filter having a transmission wavelength range in the red wavelength range. The pixel 12 marked with the symbol G is a pixel 12 provided with a green filter having a transmission wavelength range in a green wavelength range. The pixel 12 to which the symbol B is added is a pixel 12 provided with a blue filter having a transmission wavelength range in a blue wavelength range. Hereinafter, the pixel 12 having a red filter may be referred to as an R pixel 12R, the pixel 12 having a green filter may be referred to as a G pixel 12G, and the pixel 12 having a blue filter may be referred to as a B pixel 12B.

The R pixels, the G pixels, and the B pixels may be arranged according to a so-called Bayer arrangement. In the Bayer arrangement, as illustrated in, e.g., FIG. 1, in a pixel block of 2 rows×2 columns which is a minimum repetition unit, two G pixels are arranged at one diagonal position, and an R pixel and a B pixel are arranged at the other diagonal position. The pixel unit 10 is configured by repeatedly arranging the pixel blocks in the row direction and the column direction. For example, R pixels and G pixels are alternately arranged from the left end in odd-numbered rows starting from the first row, and G pixels and B pixels are alternately arranged from the left end in even-numbered rows starting from the second row. The color filter arrangement is not necessarily the Bayer arrangement and may be another arrangement.

In each row of the pixel unit 10, a control line 14 is arranged so as to extend in a first direction (lateral direction in FIG. 1). Each of the control lines 14 is connected to the pixels 12 arranged in the first direction on the corresponding row and forms a signal line common to these pixels 12. The first direction in which the control lines 14 extend may be referred to as a row direction or a horizontal direction. Each of the control lines 14 may include a plurality of signal lines. The control line 14 is connected to the vertical scanning unit 20.

In each column of the pixel unit 10, a signal output line 16 is arranged so as to extend in a second direction (vertical direction in FIG. 1) intersecting the first direction. Each of the signal output lines 16 is connected to the pixels 12 arranged in the second direction on the corresponding column and forms a signal line common to these pixels 12. The second direction in which the signal output line 16 extends may be referred to as a column direction or a vertical direction. Each of the signal output lines 16 may include a plurality of signal lines. The signal output lines 16 are connected to the AD conversion unit 30.

The vertical scanning unit 20 is a control unit having a function of generating a control signal for driving the pixels 12 in accordance with a control signal from the timing generation unit 90 and outputting the generated control signal to the pixel unit 10. A logic circuit such as a shift register or an address decoder may be used as the vertical scanning unit 20. The vertical scanning unit 20 sequentially outputs control signals to the control lines 14 of each row and performs an operation of sequentially driving the pixels 12 of the pixel unit 10 in units of rows, that is, so-called vertical scanning. The pixel signals read out from the pixels 12 in units of rows are input to the AD conversion unit 30 via the signal output lines 16.

The AD conversion unit 30 includes a plurality of AD conversion circuits and a plurality of memories corresponding to each column of the pixel unit 10. The AD conversion circuit of each column converts the pixel signal output from the pixel 12 of the corresponding column via the signal output line 16 into a digital signal and temporarily holds the digital signal in the memory of the corresponding column. The digital signals held in the memories of the respective columns are transferred to the signal output unit 80 by an operation of sequentially transferring the digital signals in accordance with a control signal from the timing generation unit 90, that is, horizontal scanning.

In the configuration example of FIG. 1, the AD conversion unit 30 is divided into a block for processing pixel signals of columns in which R pixels and G pixels are arranged and a block for processing pixel signals of columns in which G pixels and B pixels are arranged, and these blocks are arranged above and below the pixel unit 10. However, the AD conversion unit 30 does not necessarily need to be divided into a plurality of blocks.

The signal output unit 80 has a function of converting a digital signal transferred from the AD conversion unit 30 into a signal conforming to a protocol in the system and transferring the signal to the signal processing device 110 via a bus line. The external interface circuit included in the signal output unit 80 is not particularly limited. As the external interface circuit, for example, a serializer/deserializer (SerDes) transmission circuit may be applied. Examples of the SerDes transmission circuit include a low voltage differential signaling (LVDS) circuit and a scalable low voltage signaling (SLVS) circuit. The signal processing device 110 may further include a signal processing unit 120 capable of focus detection by phase difference detection.

The timing generation unit 90 has a function of generating a control signal for driving the vertical scanning unit 20 and the AD conversion unit 30 in accordance with a standard drive signal of the photoelectric conversion device input from the outside or a setting signal of the photoelectric conversion device by communication and outputting the control signal to these functional blocks. The signal supplied from the timing generation unit 90 to the vertical scanning unit 20 may include a vertical address signal, a control timing signal of the pixel 12, and the like. The signal supplied from the timing generation unit 90 to the AD conversion unit 30 may include a control timing signal, a horizontal scanning signal, and the like. At least a part of the control signals for controlling the operation of these functional blocks may be supplied from the outside of the photoelectric conversion device 100.

Each of the plurality of pixels 12 configuring the pixel unit 10 includes, as illustrated in, e.g., FIG. 2, photoelectric conversion units PDA and PDB, transfer transistors M1A and M1B, a reset transistor M2, an amplifier transistor M3, and a select transistor M4. The photoelectric conversion units PDA and PDB may be configured by photoelectric conversion elements, for example, photodiodes. The transfer transistors M1A and M1B, the reset transistor M2, the amplifier transistor M3, and the select transistor M4 may be n-channel MOS transistors.

The photoelectric conversion unit PDA has an anode connected to the ground voltage node and a cathode connected to a source of the transfer transistor M1A. The photoelectric conversion unit PDB has an anode connected to the ground voltage node and a cathode connected to a source of the transfer transistor M1B. A drain of the transfer transistor M1A and a drain of the transfer transistor M1B are connected to a source of the reset transistor M2 and a gate of the amplifier transistor M3. A node FD is a so-called floating diffusion to which the drain of the transfer transistor M1A, the drain of the transfer transistor M1B, the source of the reset transistor M2, and the gate of the amplifier transistor M3 are connected. The floating diffusion includes a capacitance component (floating diffusion capacitance) and has a function as a charge holding portion. The floating diffusion capacitance may include a p-n junction capacitance, a gate capacitance of a transistor, an interconnection capacitance, and the like. A drain of the reset transistor M2 and a drain of the amplifier transistor M3 are connected to a node to which a power supply voltage (voltage VDD) is supplied. A source of the amplifier transistor M3 is connected to a drain of the select transistor M4. A source of the select transistor M4 is connected to the signal output line 16 of the column corresponding to the pixel 12.

In the case of the circuit configuration of FIG. 2, the control line 14 of each row includes four signal lines including a signal line connected to a gate of the transfer transistor M1A, a signal line connected to a gate of the transfer transistor M1B, a signal line connected to a gate of the reset transistor M2, and a signal line connected to a gate of the select transistor M4. One of control signals tx1 and tx2 (the control signal tx1 in the pixel 12 of FIG. 2) is supplied from the vertical scanning unit 20 to the gate of the transfer transistor M1A. The other of the control signals tx1 and tx2 (the control signal tx2 in the pixel 12 of FIG. 2) is supplied from the vertical scanning unit 20 to the gate of the transfer transistor M1B. The combination of the transfer transistors M1A and M1B and the control signals tx1 and tx2 differs depending on the pixel 12, as described later. A control signal res is supplied from the vertical scanning unit 20 to a gate of the reset transistor M2. A control signal sel is supplied from the vertical scanning unit 20 to a gate of the select transistor M4. In case where each transistor is formed of an n-channel MOS transistor, the corresponding transistor is turned on when a high-level control signal is supplied from the vertical scanning unit 20. When a low-level control signal is supplied from the vertical scanning unit 20, the corresponding transistor is turned off.

The present embodiment will be described on the assumption that electrons among electron-hole pairs generated in the photoelectric conversion units PDA and PDB by light incidence are used as signal charge. In case where electrons are used as the signal charge, each transistor constituting the pixel 12 may be configured by an n-channel MOS transistor as described above. However, the signal charge is not limited to electrons, and holes may be used as the signal charge. In case where holes are used as the signal charge, the conductivity type of each transistor is opposite to that described in the present embodiment. The names of the source and the drain of the MOS transistor may vary depending on the conductivity type of the transistor and the function of interest. Some or all of the names of the source and the drain used in the present embodiment may be referred to as reverse names.

The photoelectric conversion units PDA and PDB (photoelectrically) convert the incident light into charge with an amount corresponding to the amount of the incident light and accumulate the generated charge. The transfer transistor M1A transfers the charge held by the photoelectric conversion unit PDA to the node FD by turning on. The transfer transistor M1B transfers the charge held by the photoelectric conversion unit PDB to the node FD by turning on. The charges transferred from the photoelectric conversion units PDA and PDB are held in the capacitance component (floating diffusion capacitance) of the node FD. As a result, the node FD comes into having a potential corresponding to the amount of charge transferred from the photoelectric conversion units PDA and PDB by charge-voltage conversion by the floating diffusion capacitance.

The select transistor M4 connects the amplifier transistor M3 to the signal output line 16 by turning on. The amplifier transistor M3 has the drain to which the voltage VDD is supplied and the source to which a bias current is supplied from a current source (not illustrated) via the select transistor M4 and constitutes an amplifier unit (source follower circuit) having the gate as an input node. Accordingly, the amplifier transistor M3 outputs a signal based on the voltage of the node FD to the signal output line 16 via the select transistor M4. In this sense, the amplifier transistor M3 and the select transistor M4 constitute an output unit that outputs the pixel signal according to the amount of charge held in the node FD.

The reset transistor M2 has a function of controlling supply of a voltage (voltage VDD) for resetting the node FD as a charge holding portion to the node FD. The reset transistor M2 resets the node FD to a voltage corresponding to the voltage VDD by turning on. At this time, it is also possible to reset the photoelectric conversion unit PDA to a voltage corresponding to the voltage VDD by simultaneously turning on the transfer transistor M1A. Further, by simultaneously turning on the transfer transistor M1B, the photoelectric conversion unit PDB may be reset to a voltage corresponding to the voltage VDD.

The pixel 12 of the present embodiment includes a node FD and an amplifier transistor M3 common to the two photoelectric conversion units PDA and PDB. Therefore, by transferring the charge held by the photoelectric conversion unit PDA and the charge held by the photoelectric conversion unit PDB to the node FD at the same time, the charge held by the photoelectric conversion units PDA and PDB may be added on the node FD, and a signal based on the amount of the added charge may be output. Only one of the charge held in the photoelectric conversion unit PDA and the charge held in the photoelectric conversion unit PDB is transferred to the node FD, whereby a signal based on the amount of charge held in one of the photoelectric conversion units PDA and PDB may be output.

FIG. 3 is a plan view illustrating an arrangement example of the two photoelectric conversion units PDA and PDB configuring one pixel 12 and corresponds to a plan view of the pixel 12 viewed from a direction in which light is incident. Light enters the photoelectric conversion unit PDA and the photoelectric conversion unit PDB through the microlens ML, a color filter (not illustrated), or the like. Here, the photoelectric conversion unit PDA and the photoelectric conversion unit PDB constituting one pixel 12 share one microlens ML as illustrated in FIG. 3. In other words, the photoelectric conversion unit PDA and the photoelectric conversion unit PDB are configured to receive light that has passed through different pupil regions among light incident on an imaging optical system. That is, the microlens ML causes light that has passed through a first pupil region of an exit pupil of an optical system (for example, an imaging lens) that forms an image on the pixel unit 10, to enter the photoelectric conversion unit PDA, and causes light that has passed through a second pupil region different from the first pupil region to enter the photoelectric conversion unit PDB. With this configuration, the signal based on the charge generated by the photoelectric conversion unit PDA (hereinafter referred to as “A-signal”) and the signal based on the charge generated by the photoelectric conversion unit PDB (hereinafter referred to as “B-signal”) may be used as a phase difference detection signal for distance measurement. In addition, a signal based on the total charge generated by the photoelectric conversion units PDA and PDB (hereinafter, referred to as an “(A+B)-signal”) may be used as an image forming signal.

Although FIG. 3 illustrates an example of the arrangement of the photoelectric conversion units PDA and PDB in a case where the pupil region is divided into left and right (horizontal direction), the photoelectric conversion units PDA and PDB may be arranged so as to divide the pupil region into upper and lower (vertical direction). The number of divisions of the pupil region is not necessarily two and may be more than two.

FIG. 4 is a circuit diagram illustrating a connection relationship between the pixel unit 10 and the AD conversion unit 30. FIG. 4 illustrates eight pixels 12 arranged in the first to eighth columns of the first row and eight pixels 12 arranged in the first to eighth columns of the second row among the plurality of pixels 12 included in the pixel unit 10. In each pixel 12, similarly to the layout of FIG. 3, the photoelectric conversion unit PDA is arranged on the left side, and the photoelectric conversion unit PDB is arranged on the right side. In FIG. 4, as in the block diagram of FIG. 1, it is assumed as a configuration example that the AD conversion unit 30 is divided into two blocks.

In the odd-numbered rows of the pixel unit 10 starting from the first row, the R pixels 12R and the G pixels 12G are alternately arranged. That is, the R pixels 12R are arranged in the odd-numbered columns of the odd-numbered rows, and the G pixels 12G are arranged in the even-numbered columns of the odd-numbered rows. G pixels 12G and B pixels 12B are alternately arranged in even-numbered rows of the pixel unit 10 starting from the second row. That is, the G pixels 12G are arranged in the odd-numbered columns of the even-numbered rows, and the B pixels 12B are arranged in the even-numbered columns of the even-numbered rows.

A signal line for supplying the control signal tx1 to the pixels 12 on the corresponding row and a signal line for supplying the control signal tx2 to the pixels 12 on the corresponding row are arranged in each row of the pixel unit 10. In FIG. 4, symbols for distinguishing the corresponding pixel rows are added to the symbols of the control signals tx1 and tx2. For example, the control signal tx1 supplied to the pixel 12 in the n-th row is represented by a symbol tx1[n-1] appended with [n-1], and the control signal tx2 supplied to the pixel 12 in the (n+1)-th row is represented by a symbol tx2[n] appended with [n].

The connections of the signal lines supplying the control signals tx1 and tx2 to the pixels 12 in each row to the transfer transistors M1A and M1B are determined for each pixel block of 2 rows×2 columns constituting the minimum repeating unit of the Bayer arrangement. The pixel blocks adjacent to each other in the row direction have different connections to the transfer transistors M1A and M1B. For example, in the R pixel 12R in the first row and the first column, the G pixel 12G in the first row and the second column, the G pixel 12G in the second row and the first column, and the B pixel 12B in the second row and the second column, the control signal tx1 is supplied to the transfer transistor M1A, and the control signal tx2 is supplied to the transfer transistor M1B. In the R pixel 12R in the first row and the third column, the G pixel 12G in the first row and the fourth column, the G pixel 12G in the second row and the third column, and the B pixel 12B in the second row and the fourth column, the control signal tx1 is supplied to the transfer transistor M1B, and the control signal tx2 is supplied to the transfer transistor M1A.

In other words, the control signal tx1 is supplied to the transfer transistor M1A of one pixel 12 and the control signal tx2 is supplied to the transfer transistor M1A of the other pixel 12 among the two pixels 12 adjacent to each other in the row direction and having sensitivity to the same color. Further, the control signal tx2 is supplied to the transfer transistor M1B of the one pixel 12, and the control signal tx1 is supplied to the transfer transistor M1B of the other pixel 12.

In FIG. 4, in order to illustrate the relationship between the control signals tx1 and tx2 and the photoelectric conversion units PDA and PDB in which charge transfer is performed, the signal lines to which the control signals tx1 and tx2 are supplied are associated with the photoelectric conversion units PDA and PDB by providing black dots therebetween.

The signal output lines 16 arranged in each column of the pixel unit 10 are divided into a first group connected to a first block of the AD conversion unit 30 and a second group connected to a second block of the AD conversion unit 30. For example, in the configuration example of FIG. 1, the AD conversion unit 30 arranged on the lower side of the pixel unit 10 may be the first block, and the AD conversion unit 30 arranged on the upper side of the pixel unit 10 may be the second block. The signal output lines 16 belonging to the first group may be signal output lines 16 arranged in odd-numbered columns of the pixel unit 10 starting from the first column. In addition, the signal output lines 16 belonging to the second group may be the signal output lines 16 arranged in even-numbered columns of the pixel unit 10 starting from the second column. In this case, the signal of the R pixel 12R and the signal of the G pixel 12G arranged in the same column as the R pixel 12R are processed in the first block of the AD conversion unit 30. The signal of the B pixel 12B and the signal of the G pixel 12G arranged in the same column as the B pixel 12B are processed in the second block of the AD conversion unit 30. FIG. 4 illustrates only the first block of the AD conversion unit 30 connected to the signal output line 16 of the first group. The second block of the AD conversion unit 30 is the same as the first block except that it is connected to the second group of signal output lines 16.

The AD conversion unit 30 includes a plurality of column AD conversion units (column ADCs) 32 and a plurality of switches SW1 corresponding to the number of signal output lines 16 to be connected. Each of the plurality of column AD conversion units 32 is connected to the signal output line 16 of the corresponding column. In FIG. 4, the column AD conversion units 32 arranged corresponding to the first column, the third column, the fifth column, and the seventh column of the pixel unit 10 are distinguished from each other by being represented by reference numerals 32(0), 32(1), 32(2), and 32(3). One terminal of each of the plurality of switches SW1 is connected to the column AD conversion unit 32 of the corresponding column. In FIG. 4, the switches SW1 connected to the column AD conversion units 32(0), 32(1), 32(2), and 32(3) are distinguished by being represented by reference numerals SW1(0), SW1(1), SW1(2), and SW1(3), respectively. The other terminals of the switches SW1(0) and SW1(2) are connected to a horizontal transfer line 34A. The other terminals of the switches SW1(1) and SW1(3) are connected to a horizontal transfer line 34B.

The column AD conversion unit 32 has a function of converting the pixel signal output to the signal output line 16 from an analog signal to a digital signal. The column AD conversion unit 32 may include, for example, a ramp-type AD converter. The ramp-type AD converter has a comparator (not illustrated) for comparing a pixel signal and a ramp signal and holds, as a digital value of the pixel signal, a count value of a time measurement counter from the timing of starting the comparison of the signals to the timing of the output signal of the comparator being inverted. In FIG. 4, digital signals obtained by AD conversion in the column AD conversion unit 32(0), the column AD conversion unit 32(1), the column AD conversion unit 32(2), and the column AD conversion unit 32(3) are denoted by reference numerals ado(0), ado(1), ado(2), and ado(3), respectively. The AD converter constituting the column AD conversion unit 32 is not necessarily a ramp-type AD converter and may be another AD converter such as a delta-sigma-type AD converter, a successive approximation-type AD converter, and the like.

The column AD conversion units 32 corresponding to the third column, the seventh column, . . . of the pixel unit 10 (column AD conversion unit 32(1), column AD conversion unit 32(3), . . . ) are configured to be capable of receiving a control signal psave. The control signal psave is a control signal for performing on/off control of the column AD conversion units 32. For example, the column AD conversion units 32(1), 32(3), . . . are turned off when the control signal psave is at high-level, and the column AD conversion units 32(1), 32(3), . . . are turned on when the control signal psave is at low-level. When the column AD conversion units 32(1), 32(3),. . . are not used, they are turned off to stop the AD conversion operation, thereby reducing power consumption. Note that setting the column AD conversion unit 32 to an off-state indicates that the column AD conversion unit 32 is set to a state in which the column AD conversion unit 32 does not output the AD conversion result and may include stopping power supply to the column AD conversion unit 32, stopping data supply or clock supply, and the like.

Although the control signal psave is input to the column AD conversion units 32 corresponding to the third column, the seventh column, . . . in FIG. 4, the control signal psave may be input to the column AD conversion units 32 corresponding to the first column, the fifth column, . . . (the column AD conversion unit 32(0), the column AD conversion unit 32(2), . . . ). In this case, the power consumption may be reduced by turning off the column AD conversion units 32(0), 32(2), . . . when they are not used.

The switches SW1(0), SW1(1), SW1(2), and SW1(3) are controlled by control signals hadr(0), hadr(1), hadr(2), and hadr(3), respectively. For example, the corresponding switch SW1 is turned on when the control signal hadr is at high-level, and the corresponding switch SW1 is turned off when the control signal hadr is at low-level. The digital data held by the column AD conversion unit 32 is output to one of the horizontal transfer lines 34A and 34B connected to the switch SW1 of the corresponding column, when the switch SW1 of the corresponding column is turned on.

The signal output to the horizontal transfer line 34A is output from the AD conversion unit 30 via a node N1A. The signal output to the horizontal transfer line 34B is output from the AD conversion unit 30 via a node N1B. In this specification, a signal propagation path from the node N1A to a first input node (a node N2A described later) of the signal processing unit 120 may be referred to as a channel chA. A signal propagation path from the node N1B to a second input node (a node N2B described later) of the signal processing unit 120 may be referred to as a channel chB.

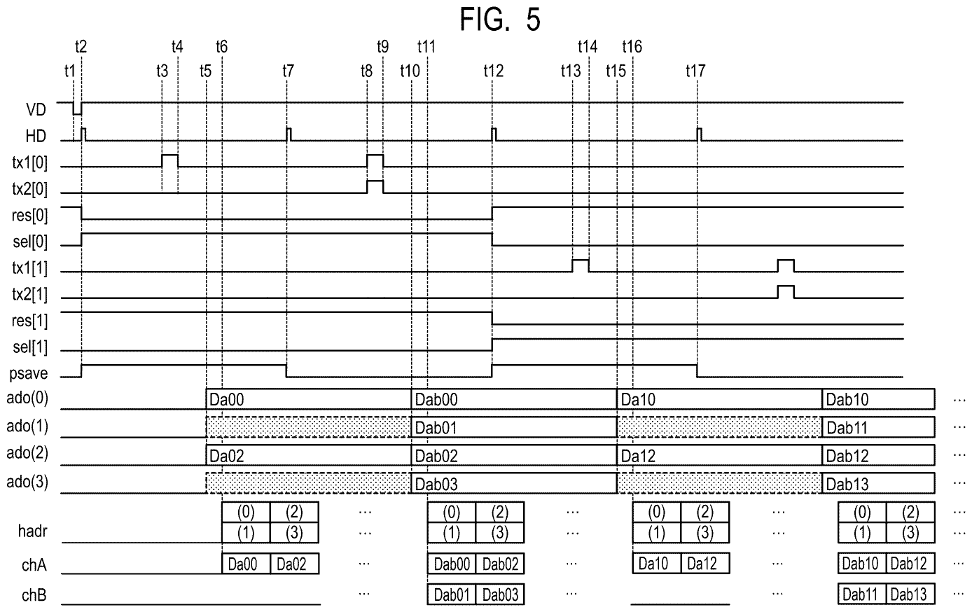

Next, a method of driving the photoelectric conversion device according to the present embodiment will be described with reference to FIG. 5. FIG. 5 is a timing chart illustrating a method of driving the photoelectric conversion device according to the present embodiment. FIG. 5 illustrates waveforms of a vertical synchronization signal VD, a horizontal synchronization signal HD, and the control signals tx1, tx2, res, sel, and psave, values of the digital signal ado, information of a column selected by the control signal hadr, and values of data output to the channels chA and chB. Symbols [0] and [1] attached to the control signals tx1, tx2, res, and sel represent row numbers.

Just before time t1, it is assumed that the control signals tx1, tx2, and sel and the control signal psave of each row are at low-level, and the control signal res of each row is at high-level.

At the time t1, the timing generation unit 90 controls the vertical synchronization signal VD from high-level to low-level. As a result, the operation of one frame is started.

At the subsequent time t2, the timing generation unit 90 controls the horizontal synchronization signal HD from low-level to high-level. As a result, the operation in one horizontal period is started. This one horizontal period is an acquisition period of a phase difference detection signal.

Further, at the time t2, the timing generation unit 90 controls the control signal psave from low-level to high-level. As a result, the column AD conversion units 32(1), 32(3), . . . are turned off.

Further, at the time t2, the vertical scanning unit 20 controls the control signal res[0] of the first row from high-level to low-level and controls the control signal sel[0] of the first row from low-level to high-level. As a result, the reset transistor M2 of each of the pixels 12 in the first row is turned off, and the reset state of the node FD is canceled. In addition, the select transistor M4 of each of the pixels 12 in the first row is turned on, and the pixels 12 in the first row are in a selection state in which the pixel signal can be output.

In the subsequent period from time t3 to time t4, the vertical scanning unit 20 maintains the control signal tx2[0] of the first row at low-level and controls the control signal tx1[0] of the first row from low-level to high-level. Accordingly, the transfer transistor M1A or the transfer transistor M1B of each of the pixels 12 in the first row that has received the control signal tx1[0] is turned on, and the charge accumulated in the photoelectric conversion unit PDA or the photoelectric conversion unit PDB of each of the pixels 12 in the first row is transferred to the node FD. As a result, the pixel signal based on the charge accumulated in the photoelectric conversion unit PDA of the pixel 12 in the first row is output to each of the signal output lines 16 in the first and fifth columns. Also, the pixel signal based on the charge accumulated in the photoelectric conversion unit PDB of the pixel 12 in the first row is output to each of the signal output lines 16 in the third and seventh columns. That is, the pixel signal based on the charge accumulated in the photoelectric conversion unit PDA and the pixel signal based on the charge accumulated in the photoelectric conversion unit PDB are alternately read out to the column AD conversion units 32(0), 32(1), 32(2), 32(3), . . . . In FIG. 4, the photoelectric conversion units PDA and PDB from which signals are read out in this period are represented by white blocks, and the photoelectric conversion units PDA and PDB from which signals are not read out in this period are represented by hatched blocks.

After the time t4, the column AD conversion unit 32 of each column performs the AD conversion on the pixel signal read out to the signal output line 16 from an analog signal to a digital signal. It is assumed here that the result of the AD conversion in the column AD conversion unit 32 of each column is determined by time t5 after the time t4. Here, it is assumed that the value of the digital signal ado(0) output from the column AD conversion unit 32(0) is Da00, and the value of the digital signal ado(2) output from the column AD conversion unit 32(2) is Da02. Since the column AD conversion units 32(1) and 32(3) are in off-state and the data supply and the clock supply are stopped, the digital signals ado(1) and ado(3) output from the column AD conversion units 32(1) and 32(3) are invalid signals. In FIG. 4, the invalid signals are represented by shaded blocks.

At the subsequent time t6, the timing generation unit 90 supplies the control signal (horizontal scanning signal) hadr to the AD conversion unit 30 and sequentially transfers the digital signals held by the column AD conversion units 32 to the signal processing unit 120 in the subsequent stage for every two columns. First, in the first cycle of horizontal scanning, the AD conversion unit 30 outputs the digital signal ado(0) held by the column AD conversion unit 32(0) to the horizontal transfer line 34A in accordance with the control signal hadr(0) input from the timing generation unit 90. Further, the AD conversion unit 30 outputs the digital signal ado(1) held by the column AD conversion unit 32(1) to the horizontal transfer line 34B in accordance with the control signal hadr(1) input from the timing generation unit 90. Next, in the next cycle of horizontal scanning, the AD conversion unit 30 outputs the digital signal ado(2) held by the column AD conversion unit 32(2) to the horizontal transfer line 34A in accordance with the control signal hadr(2) input from the timing generation unit 90. Further, the AD conversion unit 30 outputs the digital signal ado(3) held by the column AD conversion unit 32(3) to the horizontal transfer line 34B in accordance with the control signal hadr(3) input from the timing generation unit 90. As a result, the data of the value Da00 and the data of the value Da02 are sequentially output to the horizontal transfer line 34A, and the invalid signals are output to the horizontal transfer line 34B. That is, only the signals (A-signal) based on the amount of charge of the photoelectric conversion unit PDA are output to the horizontal transfer line 34A, and the invalid signals are output to the horizontal transfer line 34B. Thereafter, the subsequent cycles of horizontal scanning are sequentially performed.

At the subsequent time t7, the horizontal synchronization signal HD output from the timing generation unit 90 transitions from low-level to high-level again, and the operation of the next one horizontal period is started. This one horizontal period is an acquisition period of the image forming signal.

Further, at the time t7, the timing generation unit 90 controls the control signal psave from high-level to low-level. As a result, the column AD conversion units 32(1), 32(3), . . . are turned on. Although the horizontal transfer operation started from the time t6 is continued at this time, the operation from the pixel driving to the AD conversion after the time t7 may be performed in parallel with the horizontal transfer operation because the signal held in the memory of the column AD conversion unit 32 is read out in the horizontal transfer operation.

In a subsequent period from time t8 to time t9, the vertical scanning unit 20 controls the control signals tx1[0] and tx2[0] of the first row to high-level. As a result, the transfer transistors M1A and M1B of each of the pixels 12 on the first row are turned on, and the charges accumulated in the photoelectric conversion units PDA and PDB are transferred to the common node FD. As a result, a pixel signal based on the total amount of charges accumulated in the photoelectric conversion units PDA and PDB is output to the signal output line 16 of each column.

After the time t9, the column AD conversion unit 32 of each column performs the AD conversion on the pixel signal read out to the signal output line 16 from an analog signal to a digital signal. It is assumed here that the result of the AD conversion in the column AD conversion unit 32 of each column is determined by time t10 after the time t9. Here, it is assumed that the value of the digital signal ado(0) output from the column AD conversion unit 32(0) is Dab00, and the value of the digital signal ado(1) output from the column AD conversion unit 32(1) is Dab01. Further, it is assumed that the value of the digital signal ado(2) output from the column AD conversion unit 32(2) is Dab02, and the value of the digital signal ado(3) output from the column AD conversion unit 32(3) is Dab03. It is assumed that the horizontal transfer operation of the phase difference detection signal started from time t6 is completed by time t10.

At the subsequent time t11, the timing generation unit 90 supplies the control signal (horizontal scanning signal) hadr to the AD conversion unit 30 and sequentially transfers the digital signals held by the column AD conversion units 32 to the signal processing unit 120 in the subsequent stage for every two columns. First, in the first cycle of horizontal scanning, the AD conversion unit 30 outputs the digital signal ado(0) held by the column AD conversion unit 32(0) to the horizontal transfer line 34A in accordance with the control signal hadr(0) input from the timing generation unit 90. Further, the AD conversion unit 30 outputs the digital signal ado(1) held by the column AD conversion unit 32(1) to the horizontal transfer line 34B in accordance with the control signal hadr(1) input from the timing generation unit 90. Next, in the next cycle of horizontal scanning, the AD conversion unit 30 outputs the digital signal ado(2) held by the column AD conversion unit 32(2) to the horizontal transfer line 34A in accordance with the control signal hadr(2) input from the timing generation unit 90. Further, the AD conversion unit 30 outputs the digital signal ado(3) held by the column AD conversion unit 32(3) to the horizontal transfer line 34B in accordance with the control signal hadr(3) input from the timing generation unit 90. As a result, the data of the value Dab00 and the data of the value Dab02 are sequentially output to the horizontal transfer line 34A, and the data of the value Dab01 and the data of the value Dab03 are sequentially output to the horizontal transfer line 34B. That is, signals ((A+B)-signals) based on the total amount of charges accumulated in the photoelectric conversion units PDA and PDB are output to the horizontal transfer lines 34A and 34B, respectively. Thereafter, the subsequent cycles of horizontal scanning are sequentially performed.

From the subsequent time t12, the phase difference detection signals of the pixels 12 in the second row are acquired in the same manner as the operation from the time t2. That is, after time t14, the column AD conversion unit 32 of each column performs AD conversion on the pixel signal read out to the signal output line 16 from an analog signal to a digital signal. It is assumed here that the result of the AD conversion in the column AD conversion unit 32 of each column is determined by time t15 after time t14. Here, it is assumed that the value of the digital signal ado(0) output from the column AD conversion unit 32(0) is Da10, and the value of the digital signal ado(2) output from the column AD conversion unit 32(2) is Da 12. After time t16, the data of the value Da10 and the data of the value Da12 are sequentially output to the horizontal transfer line 34A, and invalid signals are output to the horizontal transfer line 34B.

From the subsequent time t17, the image forming signals of the pixels 12 in the second row are acquired in the same manner as the operation from the time t7. Here, it is assumed that the value of the digital signal ado(0) output from the column AD conversion unit 32(0) is Dab10, and the value of the digital signal ado(1) output from the column AD conversion unit 32(1) is Dab11. Further, it is assumed that the value of the digital signal ado(2) output from the column AD conversion unit 32(2) is Dab12, and the value of the digital signal ado(3) output from the column AD conversion unit 32(3) is Dab13. In this case, the data of the value Dab10 and the data of the value Dab12 are sequentially output to the horizontal transfer line 34A, and the data of the value Dab11 and the data of the value Dab13 are sequentially output to the horizontal transfer line 34B.

Thereafter, the signals of the pixels 12 of the third and subsequent rows are read out in the same manner as the operation of the first row and the second row, and the operation of one frame is completed.

Although the operation in which the vertical scanning is performed by selecting one row at a time is exemplified in the above-described driving example, the vertical scanning may also be performed by selecting a plurality of rows at a time. For example, in the case of the Bayer arrangement, two rows are selected every other row, and the signals of the pixels 12 in the respective columns belonging to these rows are simultaneously output to the common signal output line 16. By operating in this manner, signals of two pixels 12 of the same color arranged in the same column may be added in a pseudo manner.

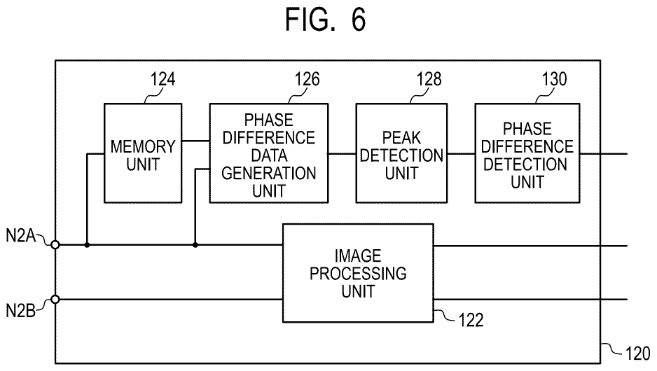

Next, a configuration example and an operation of the signal processing unit 120 will be described with reference to FIG. 6. FIG. 6 is a block diagram illustrating a configuration example of the signal processing unit 120.

As illustrated in FIG. 6, the signal processing unit 120 includes nodes N2A and N2B, an image processing unit 122, a memory unit 124, a phase difference data generation unit 126, a peak detection unit 128, and a phase difference detection unit 130. The signal of the horizontal transfer line 34A of the AD conversion unit 30 is input to the node N2A via the signal output unit 80. This signal propagation path is the channel chA described above. The signal of the horizontal transfer line 34B of the AD conversion unit 30 is input to the node N2B via the signal output unit 80. This signal propagation path is the channel chB described above. The node N2A is connected to the image processing unit 122, the memory unit 124, and the phase difference data generation unit 126. The node N2B is connected to the image processing unit 122. The memory unit 124 is connected to the phase difference data generation unit 126. The phase difference data generation unit 126 is connected to the peak detection unit 128. The peak detection unit 128 is connected to the phase difference detection unit 130.

The signal processing unit 120 performs phase difference detection processing and image processing. The phase difference detection processing is performed using the signal input from the node N2A. The image processing is performed using the signal input from the node N2A and the signal input from the node N2B.

In the acquisition period of the phase difference detection signal, only the signals (A-signals) based on the charge accumulated in the photoelectric conversion unit PDA are input to the node N2A. Further, in the acquisition period of the image forming signal, the signals ((A+B)-signals) based on the total amount of charges accumulated in the photoelectric conversion units PDA and PDB are input to the node N2A. In any operation, the signals are sequentially input to the node N2A every four columns from the first column at the left end. For example, a signal of the first column, a signal of the fifth column, a signal of the ninth column, . . . are sequentially input to the node N2A.

Further, in the acquisition period of the phase difference detection signal, the invalid signals are input to the node N2B. In the acquisition period of the image forming signal, the signals ((A+B)-signals) based on the total amount of charges accumulated in the photoelectric conversion units PDA and PDB are input to the node N2B. The signals from the columns being two columns to the right of the columns from which the signals input to the node N2A are output are sequentially input to the node N2B.

Although it is assumed in the present embodiment that the output of the photoelectric conversion device 100 is a parallel output corresponding to the channels chA and chB, the output of the photoelectric conversion device 100 may be a serial output.

Next, the phase difference detection processing in the signal processing unit 120 will be described with reference to FIG. 6.

The A-signals are sequentially input to the memory unit 124 via the node N2A during the acquisition period of the phase difference detection signal. The memory unit 124 holds the A-signals sequentially input from the node N2A. The memory unit 124 may not hold the image forming signal input via the node N2A during the acquisition period of the image forming signal.

The phase difference data generation unit 126 is configured to be capable of reading out data held by the memory unit 124. In addition, the (A+B)-signals are sequentially input to the phase difference data generation unit 126 via the node N2A during the acquisition period of the image forming signal. The phase difference data generation unit 126 sequentially reads out the A-signals of the pixel 12 corresponding to the (A+B)-signals sequentially input from the node N2A from the memory unit 124 during the acquisition period of the image forming signal, and sequentially performs subtraction processing of subtracting the data of the A-signal from the data of the (A+B)-signal. Accordingly, a signal (B-signal) corresponding to the signal based on the charge accumulated in the photoelectric conversion unit PDB is calculated.

The peak detection unit 128 receives, from the phase difference data generation unit 126, the A-signal read out from the memory unit 124 and the B-signal calculated by the phase difference data generation unit 126. The peak detection unit 128 performs peak detection on each of the received A-signal and B-signal.

The phase difference detection unit 130 receives information on the peak positions of the A-signal and the B-signal from the peak detection unit 128. Then, the phase difference detection unit 130 compares the peak position of the A-signal with the peak position of the B-signal and detects whether it is in a focus state, in a front focus state, or in a rear focus state.

The phase difference data generation unit 126, the peak detection unit 128, and the phase difference detection unit 130 may be turned off according to a control signal input via a control line (not illustrated) during the acquisition period of the phase difference detection signal. In this way, it is possible to reduce power consumption during the acquisition period of the phase difference detection signal.

Next, the image processing in the signal processing unit 120 will be described with reference to FIG. 6.

The A-signals are sequentially input from the node N2A to the image processing unit 122 during the acquisition period of the phase difference detection signal, and the (A+B)-signals are sequentially input from the nodes N2A and N2B during the acquisition period of the image forming signal. Among these signals, the image processing unit 122 processes the (A+B)-signals input during the acquisition period of the image forming signal. The image processing unit 122 performs noise removal, filter processing, RGB processing, and the like on the data of the (A+B)-signals to generate corrected signals suitable for a display system and a storage system.

The image processing unit 122 may be turned off according to a control signal input via a control line (not illustrated) during the acquisition period of the phase difference detection signal. In this way, it is possible to reduce power consumption during the acquisition period of the phase difference detection signal.

As described above, in the present embodiment, in the photoelectric conversion device that performs a focus detection using a pupil division system on an imaging plane, the A-signal and the (A+B)-signal of the first pixel are output, but the B-signal of the second pixel is not output. Therefore, it is possible to suppress the occurrence of pairs that cannot be compressed by addition, and to reduce the number of signals and the amount of signal processing. This makes it possible to reduce the circuit scale and power consumption. In addition, it is possible to further reduce power consumption by turning off the column AD conversion unit that receives a signal based on the amount of charge of the second photoelectric conversion unit read out from the second pixel in accordance with the first readout operation.

### Second Embodiment

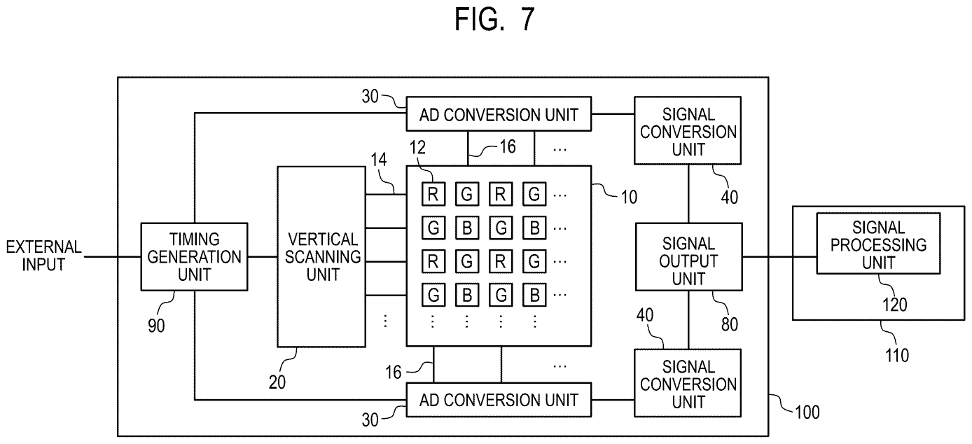

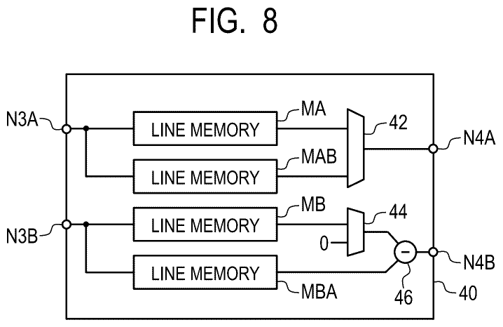

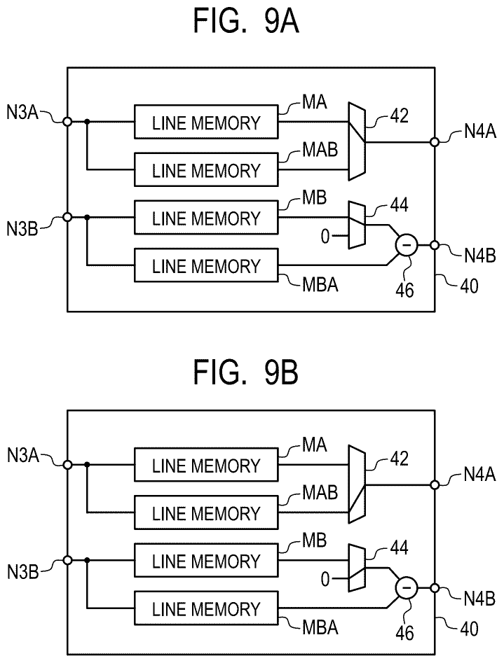

A photoelectric conversion device according to a second embodiment will be described with reference to FIG. 7 to FIG. 9B. The same components as those of the photoelectric conversion device according to the first embodiment are denoted by the same reference numerals, and description thereof will be omitted or simplified. FIG. 7 is a block diagram illustrating a schematic configuration of a photoelectric conversion device according to the present embodiment. FIG. 8 is a block diagram illustrating a configuration example of a signal conversion unit in the photoelectric conversion device according to the present embodiment. FIG. 9A and FIG. 9B are diagrams illustrating an operation of the signal conversion unit in the photoelectric conversion device according to the present embodiment.

As illustrated in FIG. 7, the photoelectric conversion device 100 according to the present embodiment further includes a signal conversion unit 40. The signal conversion unit 40 is connected between the AD conversion unit 30 and the signal output unit 80. Other features of the photoelectric conversion device according to the present embodiment are the same as those of the photoelectric conversion device according to the first embodiment.

Next, a configuration example of the signal conversion unit 40 in the photoelectric conversion device according to the present embodiment will be described with reference to FIG. 8. As illustrated in FIG. 8, the signal conversion unit 40 of the photoelectric conversion device according to the present embodiment includes nodes N3A and N3B, line memories MA, MAB, MB, and MBA, selectors 42 and 44, a subtractor 46, and nodes N4A and N4B. The node N3A is connected to the node N1A of the AD conversion unit 30. The node N4A is connected to the node N2A of the signal processing unit 120 via the signal output unit 80. The node N3B is connected to the node N1B of the AD conversion unit 30. The node N4B is connected to the node N2B of the signal processing unit 120 via the signal output unit 80.

The line memory MA and the line memory MAB are connected to the node N3A. The line memory MB and the line memory MBA are connected to the node N3B. The line memory MA is connected to one input node of the selector 42. The line memory MAB is connected to the other input node of the selector 42. The line memory MB is connected to one input node of the selector 44. A signal of data 0 (fixed value zero) is input to the other input node of the selector. An output node of the selector 44 is connected to one input node of the subtractor 46. The line memory MBA is connected to the other input node of the subtractor 46. An output node of the selector 42 is connected to the node N4A. The output node of the subtractor 46 is connected to the node N4B.

The signal conversion unit 40 has a function of performing conversion processing on the signal output from the AD conversion unit 30 in accordance with a control signal from the timing generation unit 90 and outputting the signal after the conversion processing to the signal processing unit 120 via the signal output unit 80. Details of the conversion processing in the signal conversion unit 40 will be described later.

In the acquisition period of the phase difference detection signal, only the signals (A-signals) based on the charge accumulated in the photoelectric conversion unit PDA are sequentially input to the node N3A. In the acquisition period of the image forming signal, the signals ((A+B)-signals) based on the total amount of charges accumulated in the photoelectric conversion units PDA and PDB are sequentially input to the node N3A. In any operation, the signals are sequentially input to the node N3A every four columns from the first column at the left end of the pixel unit 10.

In the acquisition period of the phase difference detection signal, only the signals (B-signals) based on the charge accumulated in the photoelectric conversion unit PDB are sequentially input to the node N3B. Further, in the acquisition period of the image forming signal, the signals ((A+B)-signals) based on the total amount of charges accumulated in the photoelectric conversion units PDA and PDB are sequentially input to the node N3B. In any operation, the signals from the columns being two columns to the right of the columns from which the signal input to the node N3A are output are sequentially input to the node N3B. In the present embodiment, unlike the first embodiment, the control signal psave input to the column AD conversion units 32(1), 32(3), . . . is always set to low-level. Therefore, the B-signal is output from the column AD conversion units 32(1), 32(3), . . . during the acquisition period of the phase difference detection signal.

Thus, the line memory MA holds the data of the A-signal input during the acquisition period of the phase difference detection signal among the data sequentially input from the node N3A. The line memory MB holds the data of the B-signal input during the acquisition period of the phase difference detection signal among the data sequentially input from the node N3B. Further, the line memory MAB holds the data of the (A+B)-signal input during the acquisition period of the image forming signal among the data sequentially input from the node N3A. The line memory MBA holds the data of the (A+B)-signal input during the acquisition period of the image forming signal among the data sequentially input from the node N3B.

The selectors 42 and 44 select and output one of the two input signals according to whether the signal output from the signal conversion unit 40 is the phase difference detection signal or the image forming signal. The subtractor 46 subtracts the signal output from the selector 44 from the signal output from the line memory MBA and outputs the result.

That is, when the signal output from the signal conversion unit 40 is the phase difference detection signal, as illustrated in FIG. 9A, the selector 42 selects the output signal of the line memory MA, and the selector 44 selects the output signal of the line memory MB. As a result, the signal-A held in the line memory MA is output from the node N4A. Further, a signal obtained by subtracting the B-signal held in the line memory MB from the (A+B)-signal held in the line memory MBA, that is, a signal corresponding to the A-signal is output from the node N4B.

When the signal output from the signal conversion unit 40 is the image forming signal, as illustrated in FIG. 9B, the selector 42 selects the output signal of the line memory MAB, and the selector 44 selects the signal of the data 0. As a result, the (A+B)-signal held in the line memory MAB is output from the node N4A. Further, a signal obtained by subtracting the signal of the data 0 from the (A+B)-signal held in the line memory MBA, that is, the (A+B)-signal held in the line memory MBA is output from the node N4B.

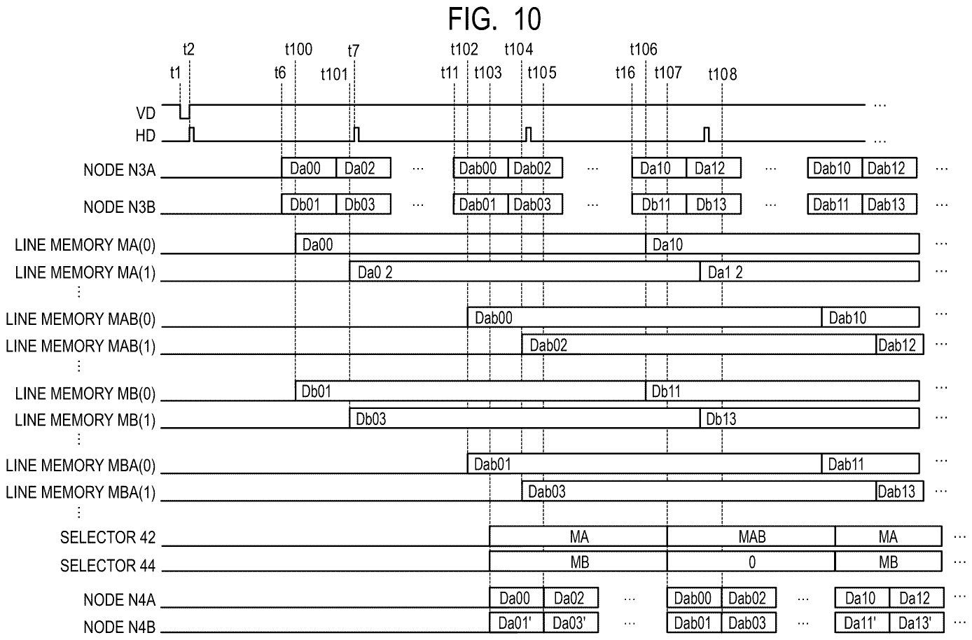

Next, a method of driving the photoelectric conversion device according to the present embodiment will be described with reference to FIG. 10. FIG. 10 is a timing chart illustrating a method of driving the photoelectric conversion device according to the present embodiment. FIG. 10 illustrates waveforms of the vertical synchronization signal VD and the horizontal synchronization signal HD, values of data in the nodes N3A and N3B, the line memories MA, MAB, MB, and MBA, and the nodes N4A and N4B, and selection of the selectors 42 and 44. Symbols (0) and (1) attached to the line memories MA, MAB, MB, and MBA represent column numbers. Since the operation at each of the timings from the time t1 to the time t11 and the time t16 is the same as the operation of the first embodiment described with reference to FIG. 5, the description thereof will be omitted as appropriate.

At the time t6, the timing generation unit 90 supplies the control signal (horizontal scanning signal) hadr to the AD conversion unit 30 and sequentially transfers the digital signals held by the column AD conversion units 32 to the subsequent signal conversion unit 40 for every two columns. First, in the first cycle of horizontal scanning, the AD conversion unit 30 outputs the digital signal ado(0) held by the column AD conversion unit 32(0) to the horizontal transfer line 34A in accordance with the control signal hadr(0) input from the timing generation unit 90. Further, the AD conversion unit 30 outputs the digital signal ado(1) held by the column AD conversion unit 32(1) to the horizontal transfer line 34B in accordance with the control signal hadr(1) input from the timing generation unit 90. Next, in the next cycle of horizontal scanning, the AD conversion unit 30 outputs the digital signal ado(2) held by the column AD conversion unit 32(2) to the horizontal transfer line 34A in accordance with the control signal hadr(2) input from the timing generation unit 90. Further, the AD conversion unit 30 outputs the digital signal ado(3) held by the column AD conversion unit 32(3) to the horizontal transfer line 34B in accordance with the control signal hadr(3) input from the timing generation unit 90.

In the present embodiment, as described above, the control signal psave supplied to the AD conversion unit 30 is fixed to low-level. That is, the column AD conversion units 32(1) and 32(3) are always in an on-state, and the digital signals ado(1) and ado(3) output from the column AD conversion units 32(1) and 32(3) are not the invalid signals but the signals (B-signals) based on the charges accumulated in the photoelectric conversion units PDB. Here, it is assumed that the value of the digital signal ado(1) output from the column AD conversion unit 32(1) is Db01, and the value of the digital signal ado(3) output from the column AD conversion unit 32(3) is Db03.

The digital signals ado(0) and ado(2) output to the horizontal transfer line 34A in this manner are sequentially output to the channel chA via the node N1A, and input to the signal conversion unit 40 via the node N3A. Further, the digital signals ado(1) and ado(3) output to the horizontal transfer line 34B are sequentially output to the channel chB via the node N1B and input to the signal conversion unit 40 via the node N3B.

At the subsequent time t100, the line memory MA holds the digital signal ado(0) (value: Da00) input from the node N3A in the line memory MA(0) in accordance with the control signal from the timing generation unit 90. Further, the line memory MB holds the digital signal ado(1) (value: Db01) input from the node N3B in the line memory MB(0) in accordance with the control signal from the timing generation unit 90.

Next, at time t101 after the digital signals ado(2) and ado(3) are output to the horizontal transfer lines 34A and 34B, the line memories MA and MB hold the digital signals ado(2) and ado(3) input from the nodes N3A and N3B. That is, the line memory MA holds the digital signal ado(2) (value: Da02) input from the node N3A in the line memory MA(1) in accordance with the control signal from the timing generation unit 90. Further, the line memory MB holds the digital signal ado(3) (value: Db03) input from the node N3B in the line memory MB(1) in accordance with the control signal from the timing generation unit 90.

In this way, in the period until the time t11, the signal conversion unit 40 holds the series of data sequentially input from the nodes N3A and N3B in the line memories MA and MB. In this way, the A-signals of the pixels 12 of the row to be read out are held in the line memory MA of the signal conversion unit 40. Further, the B-signals of the pixels 12 of the row to be read out are held in the line memory MB of the signal conversion unit 40.

At the time t11, the timing generation unit 90 supplies the control signal (horizontal scanning signal) hadr to the AD conversion unit 30 and sequentially transfers the digital signals held by the column AD conversion units 32 to the subsequent signal conversion unit 40 for every two columns. First, in the first cycle of horizontal scanning, the AD conversion unit 30 outputs the digital signal ado(0) held by the column AD conversion unit 32(0) to the horizontal transfer line 34A in accordance with the control signal hadr(0) input from the timing generation unit 90. Further, the AD conversion unit 30 outputs the digital signal ado(1) held by the column AD conversion unit 32(1) to the horizontal transfer line 34B in accordance with the control signal hadr(1) input from the timing generation unit 90. Next, in the next cycle of horizontal scanning, the AD conversion unit 30 outputs the digital signal ado(2) held by the column AD conversion unit 32(2) to the horizontal transfer line 34A in accordance with the control signal hadr(2) input from the timing generation unit 90. Further, the AD conversion unit 30 outputs the digital signal ado(3) held by the column AD conversion unit 32(3) to the horizontal transfer line 34B in accordance with the control signal hadr(3) input from the timing generation unit 90.

At the subsequent time t102, the line memory MAB holds the digital signal ado(0) (value: Dab00) input from the node N3A in the line memory MAB(0) in accordance with the control signal from the timing generation unit 90. Further, the line memory MBA holds the digital signal ado(1) (value: Dab01) input from the node N3B in the line memory MBA(0) in accordance with the control signal from the timing generation unit 90.

Next, at time t104 after the digital signals ado(2) and ado(3) are output to the horizontal transfer lines 34A and 34B, the line memories MAB and MBA hold the digital signals ado(2) and ado(3) input from the nodes N3A and N3B. That is, the line memory MAB holds the digital signal ado(2) (value: Dab02) input from the node N3A in the line memory MAB(1) in accordance with the control signal from the timing generation unit 90. The line memory MBA holds the digital signal ado(3) (value: Dab03) input from the node N3B in the line memory MBA(1) in accordance with the control signal from the timing generation unit 90.

In this way, in the period until the time t16, the signal conversion unit 40 holds the series of data sequentially input from the nodes N3A and N3B in the line memories MAB and MBA. In this way, the (A+B)-signals of the pixels 12 of the row to be read out are held in the line memories MAB and MBA of the signal conversion unit 40.

On the other hand, after time t102, the signal conversion unit 40 sequentially outputs signals based on the signals held in the line memories MA, MAB, MB, and MBA from the nodes N4A and N4B in accordance with the control signal from the timing generation unit 90.

At time 103 between the time t102 and the time t104, the selector 42 selects the line memory MA in accordance with the control signal from the timing generation unit 90. As a result, the data of the value Da00 of the line memory MA(0) is output from the node N4A. Further, the selector 44 selects the line memory MB in accordance with the control signal from the timing generation unit 90. Accordingly, data of a value Da01′ obtained by subtracting the value Db01 of the line memory MB(0) from the value Dab01 of the line memory MBA(0) is output from the node N4B.

As described above, the value Da00 is a signal (A-signal) based on the charge accumulated in the photoelectric conversion unit PDA, and the data Da01′ is a signal corresponding to the signal (A-signal) based on the charge accumulated in the photoelectric conversion unit PDA. Therefore, a signal obtained by adding the value Da00 output from the node N4A and the value Da01′ output from the node N4B is also a signal that can be used for phase difference detection in the signal processing unit 120.

When the value Dab02 is held in the line memory MAB(1) and the value Dab03 is held in the line memory MBA(1) at the time t104, data of the value Da02 of the line memory MA(1) is output from the node N4A at subsequent time t105. Further, data of a value Da03′ obtained by subtracting the value Db03 of the line memory MB(1) from the value Dab03 of the line memory MBA(1) is output from the node N4B.

In this way, in the period until time t107, the signal conversion unit 40 sequentially outputs the A-signals based on the signals held in the line memories MA, MAB, MB, and MBA from the nodes N4A and N4B.

At the subsequent time t107, the selector 42 selects the line memory MAB in accordance with the control signal from the timing generation unit 90. Thus, the data of the value Dab00 of the line memory MAB(0) is output from the node N4A. Further, the selector 44 selects the data 0 in accordance with the control signal from the timing generation unit 90. As a result, a value obtained by subtracting the data 0 from the value Dab01 of the line memory MBA(0), that is, data of the value Dab01 is output from the node N4B.

At the subsequent time t108, the signal conversion unit 40 outputs the data of the value Dab02 of the line memory MAB(1) from the node N4A in accordance with the control signal from the timing generation unit 90. Further, the signal conversion unit 40 outputs a value obtained by subtracting the data 0 from the value Dab03 of the line memory MBA(1), that is, data of the value Dab03 from the node N4B.

In this way, the signal conversion unit 40 sequentially outputs the (A+B)-signals based on the signals held in the line memories MA, MAB, MB, and MBA from the nodes N4A and N4B.

As described above, according to the present embodiment, it is possible to reduce the number of signals and the amount of signal processing by suppressing the occurrence of pairs that cannot be compressed by addition in a photoelectric conversion device that performs a focus detection using a pupil division system on an imaging plane. This makes it possible to reduce the circuit scale and power consumption. In addition, in the present embodiment, since all the phase difference detection signals may be used for phase difference detection without making a part of the phase difference detection signals be invalid signals, the phase difference detection accuracy may be improved.

In the present embodiment, a configuration example in which the signal conversion unit 40 includes the line memories MA, MAB, MB, and MBA has been described, but a frame memory may be used instead of the line memories. The memory used in the signal conversion unit 40 is not necessarily a memory dedicated to the signal conversion unit 40 and may be another memory included in the photoelectric conversion device 100. For example, the memory used in the signal conversion unit 40 may be a memory included in the AD conversion unit 30.

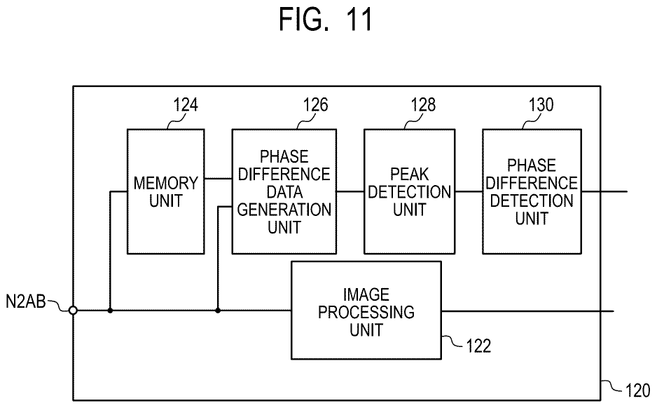

Further, in the present embodiment, an operation in which the vertical scanning is performed by selecting one row at a time, that is, a non-addition operation is exemplified, but a configuration in which signals of two or more pixels 12 are added may be adopted. For example, in the case of performing two-pixel addition in the vertical direction, two rows are selected every other row, and the signals of the pixels 12 in the respective columns belonging to these rows are simultaneously output to the common signal output line 16. By operating in this manner, signals of two pixels 12 of the same color arranged in the same column may be added in a pseudo manner. In case where the addition processing is performed in the horizontal direction, the signal of the node N4A and the signal of the node N4B may be added in digital, and the added signal may be input from the node N2AB of the signal processing unit 120 configured as illustrated in FIG. 11, for example, and the processing may be performed. With this configuration, it is possible to realize an operation of performing two-pixel addition in both the vertical direction and the horizontal direction. In case where the signals are added, it is possible to obtain an effect of reducing the bandwidth of the phase difference signal.

### Third Embodiment

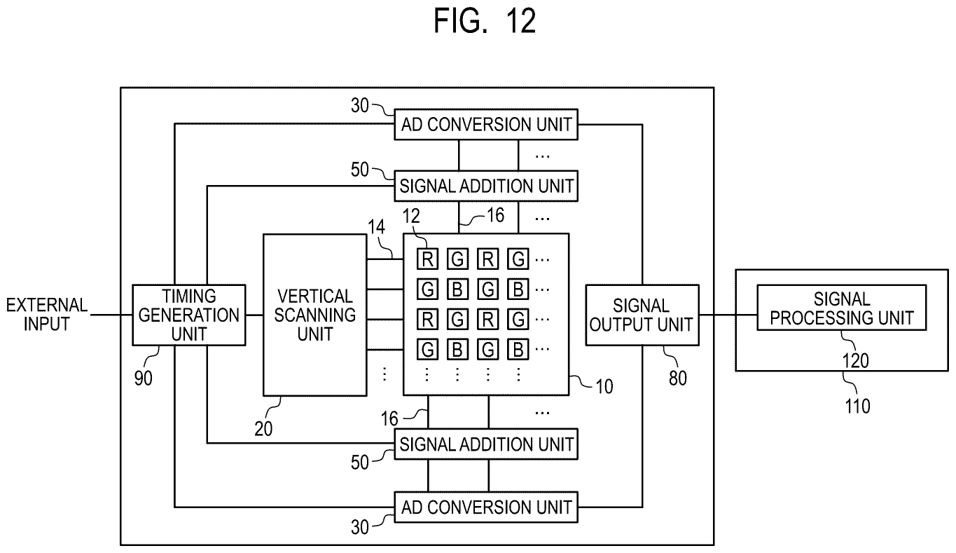

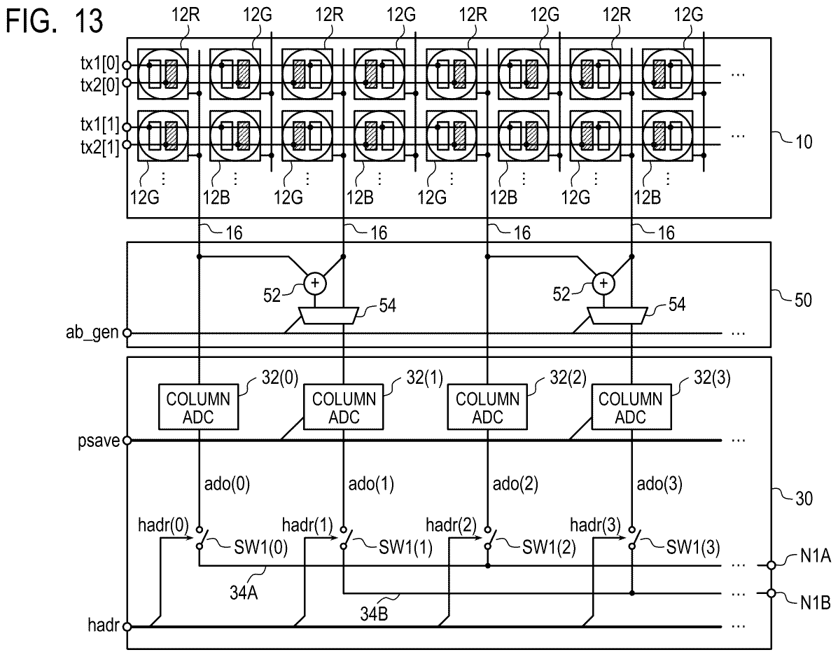

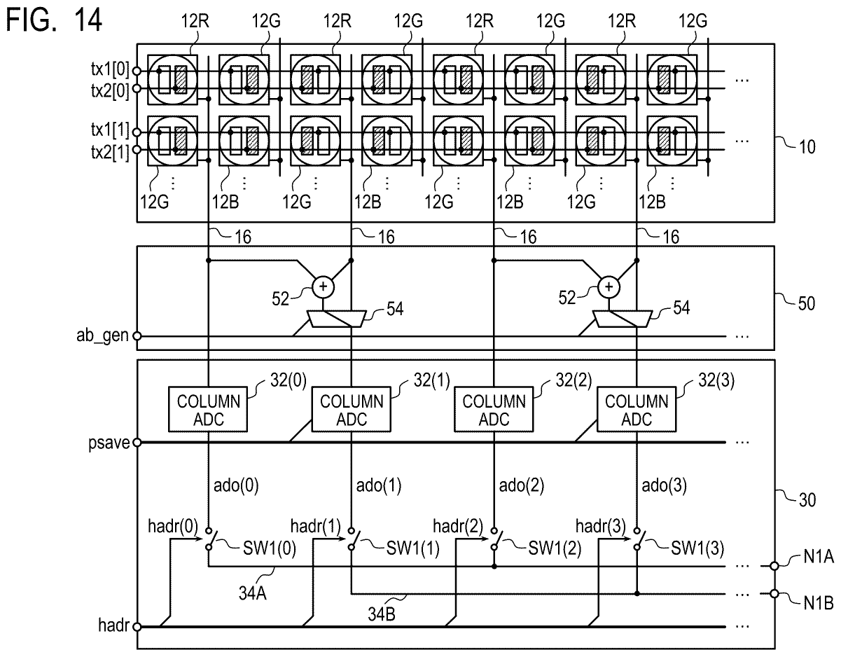

A photoelectric conversion device according to a third embodiment will be described with reference to FIG. 12 to FIG. 15. The same components as those of the photoelectric conversion devices according to the first and second embodiments are denoted by the same reference numerals, and description thereof will be omitted or simplified. FIG. 12 is a block diagram illustrating a schematic configuration of a photoelectric conversion device according to the present embodiment. FIG. 13 is a circuit diagram illustrating a connection relationship among the pixel unit, the signal addition unit, and the AD conversion unit in the photoelectric conversion device according to the present embodiment. FIG. 14 and FIG. 15 are diagrams illustrating the operation of the signal addition unit in the photoelectric conversion device according to the present embodiment.

As illustrated in FIG. 12, the photoelectric conversion device 100 according to the present embodiment further includes a signal addition unit 50. The signal addition unit 50 is connected between the pixel unit 10 and the AD conversion unit 30. The signal addition unit 50 generates an image forming signal based on a signal output from the pixel unit 10 in accordance with a control signal from the timing generation unit 90. The image forming signal generated by the signal addition unit 50 is output to the AD conversion unit 30. Other features of the photoelectric conversion device according to the present embodiment are the same as those of the photoelectric conversion device according to the first or second embodiment.

Next, a configuration example of the signal addition unit 50 in the photoelectric conversion device according to the present embodiment will be described with reference to FIG. 13. As illustrated in FIG. 13, the signal addition unit 50 of the photoelectric conversion device according to the present embodiment includes a plurality of adders 52 and a plurality of selectors 54 corresponding to a plurality of pairs each configured by two adjacent signal output lines 16. For example, in the case of the configuration example of FIG. 12, the signal output lines 16 arranged in the odd-numbered columns of the pixel unit 10 are connected to the first block of the AD conversion unit 30 arranged on the lower side of the pixel unit 10. In this case, for example, the signal output line 16 of the first column and the signal output line 16 of the third column may constitute one pair, and the signal output line 16 of the fifth column and the signal output line 16 of the seventh column may constitute another pair.

One of two input nodes of the adder 52 is connected to one of the two signal output lines 16 constituting the pair. The other of the two input nodes of the adder 52 is connected to the other of the two signal output lines 16 constituting the pair. One of two input nodes of the selector 54 is connected to an output node of the adder 52. The other of the two input nodes of the selector 54 is connected to the other of the two signal output lines 16 constituting the pair. An output node of the selector 54 is connected to the column AD conversion unit 32 corresponding to the other of the two signal output lines 16 constituting the pair. The one of the two signal output lines 16 constituting the pair is connected to the column AD conversion unit 32 corresponding to the one of the two signal output lines 16 constituting the pair.

For example, focusing on a pair of the first column and the third column, the signal output line 16 of the first column and the signal output line 16 of the third column are connected to the two input nodes of the adder 52. The output node of the adder 52 and the signal output line 16 of the third column are connected to the two input nodes of the selector 54. The output node of the selector 54 is connected to the column AD conversion unit 32(1) provided corresponding to the third column. The signal output line 16 of the first column is connected to the column AD conversion unit 32(0) provided corresponding to the first column.

The selector 54 selects one of the signals input to the two input nodes in accordance with the control signal ab_gen supplied from the timing generation unit 90, and outputs the selected signal from the output node. For example, the selector 54 selects the output signal of the adder 52 when the control signal ab_gen is at high-level and selects the other signal of the two signal output lines 16 constituting the pair when the control signal ab_gen is at low-level.

When the selector 54 selects the output signal of the adder 52, as illustrated in FIG. 14, a signal obtained by adding the signals of the two signal output lines 16 constituting the pair is input to the column AD conversion unit 32 corresponding to the other of the two signal output lines 16 constituting the pair. When the color filters are arranged in the Bayer arrangement, the signals of the two signal output lines 16 constituting the pair are signals of the pixels 12 having sensitivity to the same color. Therefore, horizontal addition of two pixels of the same color may be performed by the addition processing performed in this manner. One of the signals of the two signal output lines 16 constituting the pair is a signal (A-signal) based on the charge accumulated in the photoelectric conversion unit PDA, and the other is a signal (B-signal) based on the charge accumulated in the photoelectric conversion unit PDB. Therefore, the signal obtained by the addition processing performed in this manner is the image forming signal ((A+B)-signal).

When the selector 54 selects the other of the two signal output lines 16 constituting the pair, the selected signal is input to the column AD conversion unit 32 corresponding to the other of the two signal output lines 16 constituting the pair, as illustrated in FIG. 15. When the signal addition unit 50 is connected as illustrated in FIG. 15, the connection between the pixel unit 10 and the AD conversion unit 30 is substantially the same as the connection illustrated in FIG. 4.

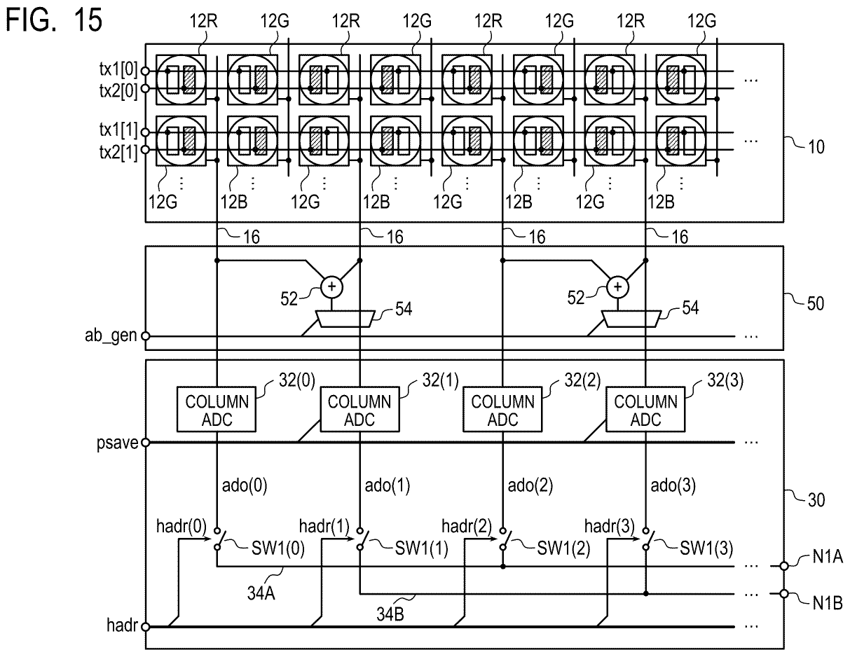

Next, a method of driving the photoelectric conversion device according to the present embodiment will be described with reference to FIG. 16. FIG. 16 is a timing chart illustrating a method of driving the photoelectric conversion device according to the present embodiment. FIG. 16 illustrates waveforms of the vertical synchronization signal VD, the horizontal synchronization signal HD, and the control signals tx1, tx2, res, sel, ab_gen, and psave. FIG. 16 also illustrates the value of the digital signal ado, the information of the column selected by the control signal hadr, and the value of the data output to the channels chA and chB. Symbols [0] and [1] attached to the control signals tx1, tx2, res, and sel represent row numbers. The description of the same operations as those of the first embodiment described with reference to FIG. 5 is omitted as appropriate.

At the time t2, the timing generation unit 90 controls the control signal ab_gen from low-level to high-level. As a result, the signal output from the selector 54 becomes the output signal of the adder 52, that is, the image forming signal. In this driving example, the control signal psave supplied to the AD conversion unit 30 is fixed to low-level.

At the subsequent time t5, the image forming signal thus output from the selector 54 is converted into a digital signal in the column AD conversion units 32(1), 32(3), . . . Here, it is assumed that the value of the digital signal ado(1) is Dab00 and the value of the digital signal ado(3) is Dab02.

The horizontal transfer operation in the period from the time t6 to the time t11 is the same as in the first embodiment. That is, the data of the value Da00 and the data of the value Da02 are sequentially output to the channel chA via the node N1A. Further, the data of the value Dab00 and the data of the value Dab02 are sequentially output to the channel chB via the node N1B.

In this manner, the phase difference detection signal and the image forming signal may be output to the channel chA and the channel chB, respectively, and both the phase difference detection signal and the image forming signal may be acquired during one HD period.

At the subsequent time t7, the vertical scanning unit 20 controls the control signals res[0] and sel[1] from low-level to high-level, controls the control signals res[1] and sel[0] from high-level to low-level, and shifts to the processing of the next row.

In the subsequent period from the time t8 to the time t9, as in the period from the time t3 to the time t4, the control signal tx1[1] transitions from low-level to high-level, while the control signal tx2[1] is maintained at low-level. After the subsequent time t12, the same operation as the operation from the time t2 is repeatedly performed.

In this manner, the operation of one frame is completed by repeatedly performing the operation of one HD period while performing the vertical scanning and reading out the signals of all the pixels 12 of the pixel unit 10.

In the driving example of the first embodiment, the phase difference detection signal and the image forming signal are alternately output to the channel chA, and the invalid signal and the image forming signal are alternately output to the channel chB. On the other hand, in the driving example of the present embodiment, the phase difference detection signals are sequentially output to the channel chA, and the image forming signals are sequentially output to the channel chB. Therefore, there is a difference in the order of data output to the channels chA and chB between the driving example of the first embodiment and the driving example of the third embodiment. Such a difference in data arrangement may be resolved by, for example, changing the configuration of the signal processing unit 120.

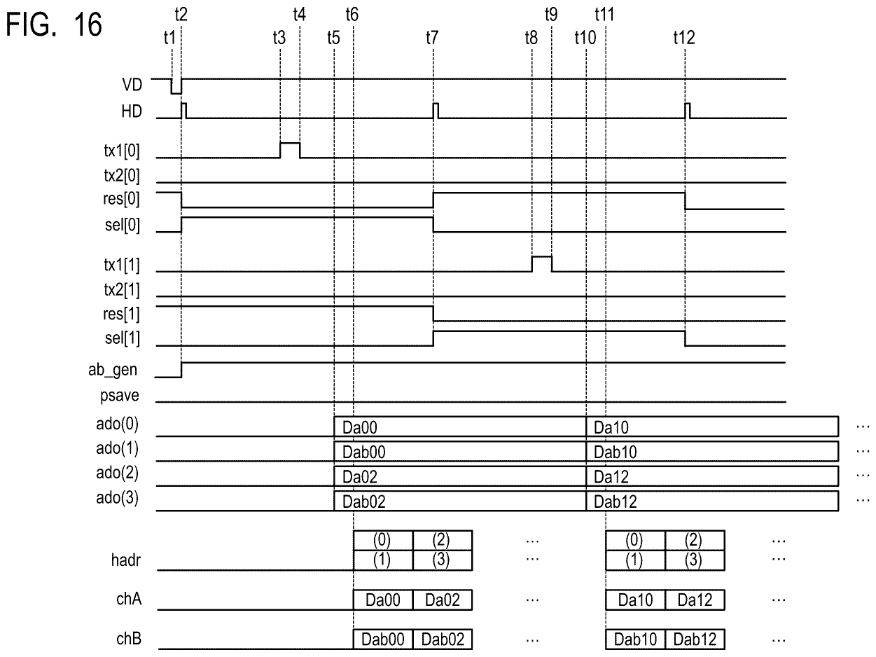

FIG. 17 is a block diagram illustrating a configuration example of the signal processing unit 120 for resolving the difference in data arrangement. In the signal processing unit 120 illustrated in FIG. 17, a selector 132 is inserted between the memory unit 124 and the phase difference data generation unit 126. The input signal to the node N2A and one of the signal selected by the selector 132 between the output signal of the memory unit 124 and the input signal to the node N2B are input to the phase difference data generation unit 126.

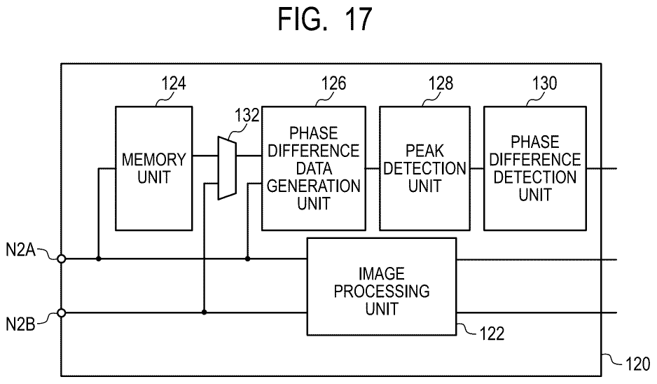

By configuring the signal processing unit 120 as described above, it is possible to select data to be input to the phase difference data generation unit 126. That is, as illustrated in FIG. 18A, when the input signal from the channel chB is selected by the selector 132, the phase difference detection signal from the channel chA and the image forming signal from the channel chB are sequentially input to the phase difference data generation unit 126. As a result, the same data arrangement as in the first embodiment may be realized. When the output signal of the memory unit 124 is selected by the selector 132 as illustrated in FIG. 18B, the signal processing unit 120 becomes substantially the same as the configuration example of FIG. 6. The output signal of the selector 132 may be controlled by a control signal supplied from the timing generation unit 90 or the like.

Alternatively, the signal output unit 80 arranged in the preceding stage of the signal processing unit 120 may perform a process of rearranging the order of the signals to be output to the signal processing unit 120 to resolve the difference in data arrangement between the channels chA and chB. In this case, the signal processing unit 120 may have a configuration similar to that of the first embodiment.

In addition, according to the configuration of the present embodiment, it is possible to dynamically switch between the driving of the first embodiment and the driving of the present embodiment. In this case, in the period in which the driving of the first embodiment is performed, the selector 54 of the signal addition unit 50 is set to the connection state of FIG. 15, and the selector 132 of the signal processing unit 120 is set to the connection state of FIG. 18B. In the period in which the driving of the present embodiment is performed, the selector 54 of the signal addition unit 50 is set to the connection state of FIG. 14, and the selector 132 of the signal processing unit 120 is set to the connection state of FIG. 18A.

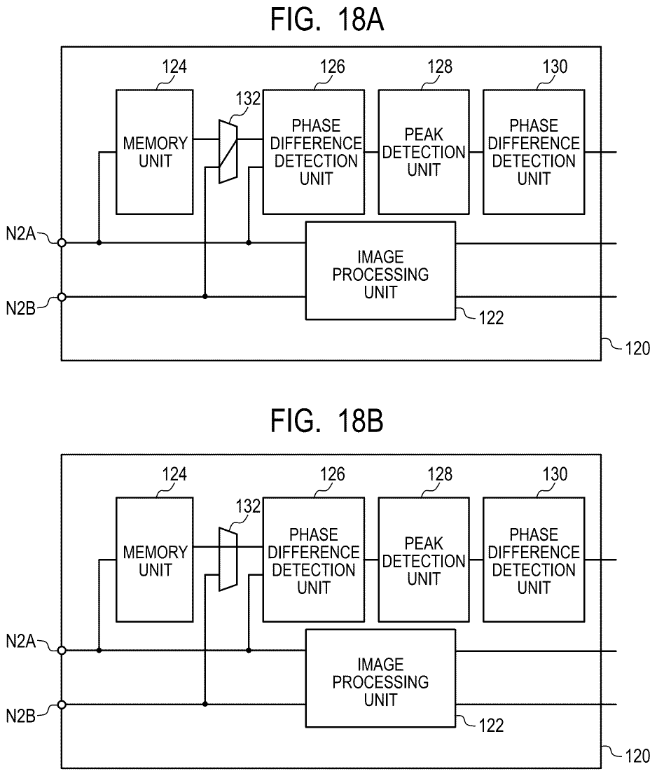

FIG. 19 is a timing chart illustrating a driving example in a case where the driving according to the first embodiment and the driving according to the present embodiment are dynamically switched. FIG. 19 illustrates waveforms of the vertical synchronization signal VD, the horizontal synchronization signal HD, and the control signals tx1, tx2, res, sel, ab_gen, and psave. FIG. 19 also illustrates the values of the digital signal ado, the information of the column selected by the control signal hadr, and the values of the data output to the channels chA and chB. Symbols [0], [1], and [2] attached to the control signals tx1, tx2, res, and sel represent row numbers. Note that the description of the same operations as those of the first embodiment described with reference to FIG. 5 and those of the present embodiment described with reference to FIG. 16 will be omitted as appropriate.

A period from the time t2 to the time t12 is a driving period in which the operation of the first embodiment is performed. During this period, the selector 54 of the signal addition unit 50 is set to the connection state of FIG. 15, the selector 132 of the signal processing unit 120 is set to the connection state of FIG. 18B, and the control signal ab_gen is set to low-level. The control signal psave is set to high-level during a period from the time t2 to the time t7 and is set to low-level after the time t7. Under these settings, the operation for every two HD periods is repeated while performing the vertical scanning.

The period after the time t12 is a driving period in which the operation of the present embodiment is performed. During this period, the selector 54 of the signal addition unit 50 is set to the connection state of FIG. 14, and the selector 132 of the signal processing unit 120 is set to the connection state of FIG. 18A. During this period, the control signal ab_gen is set to high-level, and the control signal psave is set to low-level. Under these settings, the operation for every one HD period is repeatedly performed while performing the vertical scanning.

By performing the above-described control while the signals of all the pixels 12 in the pixel unit 10 are read out, the driving of the first embodiment and the driving of the present embodiment may be mixed in the operation of one frame. Accordingly, it is possible to reduce power consumption in a period in which a high frame rate is not required while improving the frame rate. In addition, by setting the signal addition unit 50 to the connection state of FIG. 15 in the driving period of the first embodiment and setting the signal addition unit 50 to the connection state of FIG. 14 in the driving period of the present embodiment, it is possible to align the arrangement of the data output from the channels chA and chB.

Similarly, the driving of the second embodiment and the driving of the present embodiment may be dynamically switched. Accordingly, it is possible to increase the resolution in a period in which a high frame rate is not required while improving the frame rate.

As described above, according to the present embodiment, it is possible to reduce the number of signals and the amount of signal processing by suppressing the occurrence of pairs that cannot be compressed by addition in a photoelectric conversion device that performs a focus detection using a pupil division system on an imaging plane. This makes it possible to reduce the circuit scale and power consumption. In addition, in the present embodiment, since the phase difference detection signal and the image forming signal are output during one HD period, the frame rate may be improved as compared with the first embodiment.

Further, in the present embodiment, an operation in which the vertical scanning is performed by selecting one row at a time, that is, a non-addition operation is exemplified, but a configuration in which signals of two or more pixels are added may be adopted. For example, in the case of performing two-pixel addition in the vertical direction, two rows are selected every other row, and the signals of the pixels 12 in the respective columns belonging to these rows are simultaneously output to the common signal output line 16. By operating in this manner, signals of two pixels 12 of the same color arranged in the same column may be added in a pseudo manner. When the addition processing is performed in the horizontal direction, the signal of the node N4A and the signal of the node N4B may be added in digital, and the added signal may be input from the node N2AB of the signal processing unit 120 configured as illustrated in FIG. 11, for example, and the processing may be performed. With this configuration, it is possible to realize an operation of performing two-pixel addition in both the vertical direction and the horizontal direction.

### Fourth Embodiment

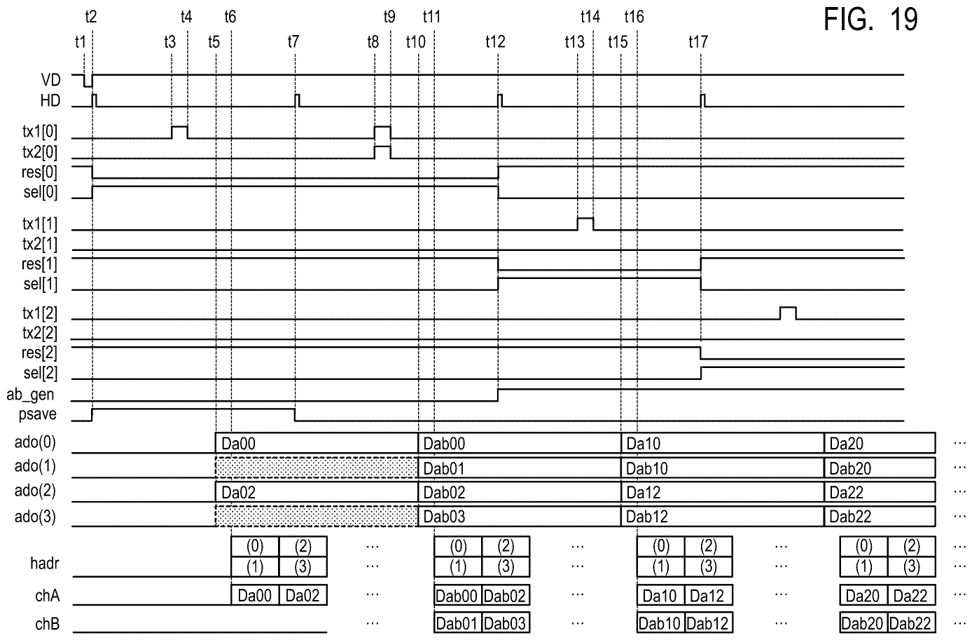

A photoelectric conversion system according to a fourth embodiment will be described with reference to FIG. 20. FIG. 20 is a block diagram illustrating a schematic configuration of a photoelectric conversion system according to the present embodiment.

The photoelectric conversion device 100 described in the first to third embodiments may be applied to various photoelectric conversion systems. Examples of applicable photoelectric conversion systems include digital still cameras, digital camcorders, surveillance cameras, copying machines, facsimiles, mobile phones, on-vehicle cameras, observation satellites, and the like. A camera module including an optical system such as a lens and an imaging device is also included in the photoelectric conversion system. FIG. 20 exemplifies a block diagram of a digital still camera as one of these.

The photoelectric conversion system 200 illustrated in FIG. 20 includes an imaging device 201, a lens 202 that forms an optical image of an object on the imaging device 201, an aperture 204 that changes the amount of light passing through the lens 202, and a barrier 206 that protects the lens 202. The lens 202 and the aperture 204 constitute an optical system that focuses light onto the imaging device 201. The imaging device 201 is the photoelectric conversion device 100 described in any one of the first to third embodiments and converts the optical image formed by the lens 202 into image data.

The photoelectric conversion system 200 further includes a signal processing unit 208 that processes an output signal output from the imaging device 201. The signal processing unit 208 generates image data from the digital signal output from the imaging device 201. Further, the signal processing unit 208 performs various corrections and compressions as necessary and outputs the processed image data. The imaging device 201 may include an AD conversion unit that generates a digital signal to be processed by the signal processing unit 208. The AD conversion unit may be formed on a semiconductor layer (semiconductor substrate) on which the photoelectric conversion unit of the imaging device 201 is formed or may be formed on a semiconductor layer different from the semiconductor layer on which the photoelectric conversion unit of the imaging device 201 is formed. The signal processing unit 208 may be formed on the same semiconductor layer as the imaging device 201.

The photoelectric conversion system 200 further includes a memory unit 210 for temporarily storing image data and an external interface unit (external I/F unit) 212 for communicating with an external computer or the like. The photoelectric conversion system 200 further includes a storage medium 214 such as a semiconductor memory for performing storing or reading out of imaging data, and a storage medium control interface unit (storage medium control I/F unit) 216 for performing storing on or reading out from the storage medium 214. The storage medium 214 may be built in the photoelectric conversion system 200 or may be detachable.

The photoelectric conversion system 200 further includes a general control/operation unit 218 that performs various calculations and controls the entire digital still camera, and a timing generation unit 220 that outputs various timing signals to the imaging device 201 and the signal processing unit 208. Here, the timing signal or the like may be input from the outside, and the photoelectric conversion system 200 may include at least the imaging device 201 and the signal processing unit 208 that processes the output signal output from the imaging device 201.

The imaging device 201 outputs an imaging signal to the signal processing unit 208. The signal processing unit 208 performs predetermined signal processing on the imaging signal output from the imaging device 201, and outputs the processed image data. The signal processing unit 208 generates an image using the imaging signal.

As described above, according to the present embodiment, it is possible to realize a photoelectric conversion system to which the photoelectric conversion device 100 according to any one of the first to third embodiments is applied.

### Fifth Embodiment

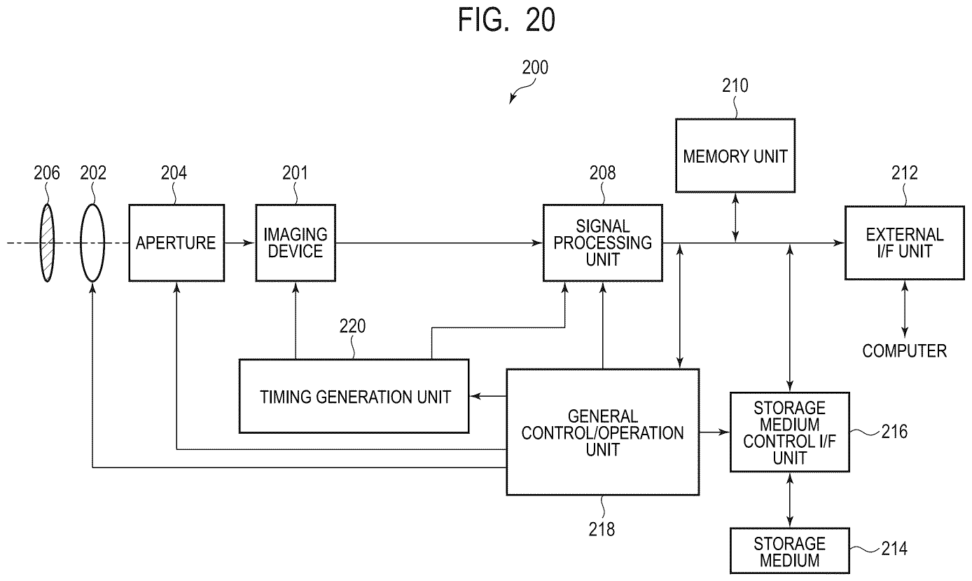

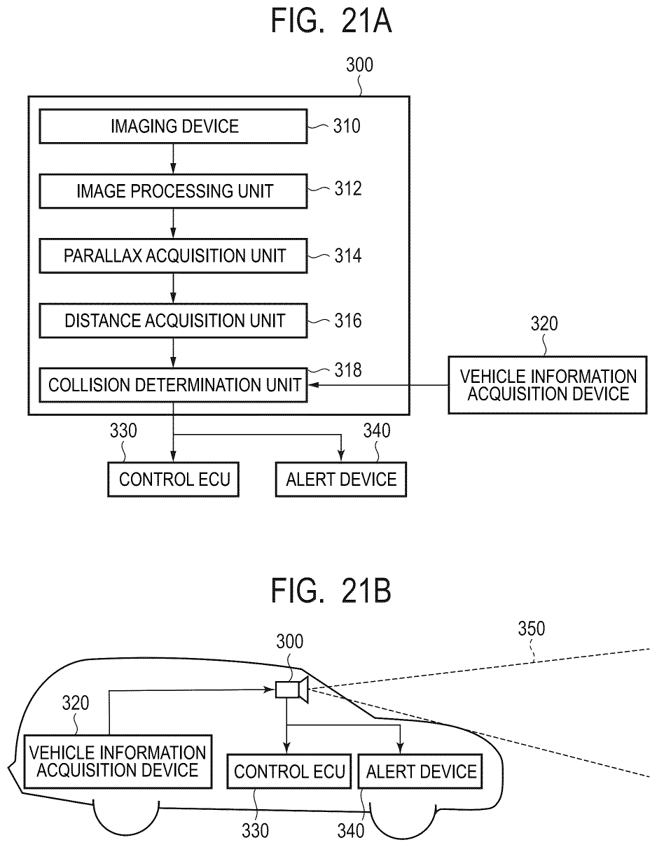

The photoelectric conversion system and a movable object according to a fifth embodiment will be described with reference to FIG. 21A and FIG. 21B. FIG. 21A is a diagram illustrating a configuration of a photoelectric conversion system according to the present embodiment. FIG. 21B is a diagram illustrating a configuration of a movable object according to the present embodiment.

FIG. 21A illustrates an example of a photoelectric conversion system related to an on-vehicle camera. The photoelectric conversion system 300 includes an imaging device 310. The imaging device 310 is the photoelectric conversion device 100 according to any one of the first to third embodiments. The photoelectric conversion system 300 includes an image processing unit 312 that performs image processing on a plurality of image data acquired by the imaging device 310, and a parallax acquisition unit 314 that calculates parallax (phase difference of parallax images) from the plurality of image data acquired by the imaging device 310. The photoelectric conversion system 300 further includes a distance acquisition unit 316 that calculates a distance to an object based on the calculated parallax, and a collision determination unit 318 that determines whether there is a collision possibility based on the calculated distance. Here, the parallax acquisition unit 314 and the distance acquisition unit 316 are examples of a distance information acquisition unit that acquires distance information to the object. That is, the distance information is information related to a parallax, a defocus amount, a distance to the object, and the like. The collision determination unit 318 may determine the collision possibility using any of the distance information. The distance information acquisition unit may be realized by dedicatedly designed hardware or may be realized by a software module. Further, it may be realized by a field programmable gate array (FPGA), an application specific integrated circuit (ASIC), or the like, or may be realized by a combination of these.

The photoelectric conversion system 300 is connected to a vehicle information acquisition device 320 and may acquire vehicle information such as a vehicle speed, a yaw rate, and a steering angle. Further, the photoelectric conversion system 300 is connected to a control ECU 330 which is a control device that outputs a control signal for generating a braking force to the vehicle based on the determination result of the collision determination unit 318. The photoelectric conversion system 300 is also connected to an alert device 340 that issues an alert to the driver based on the determination result of the collision determination unit 318. For example, when the determination result of the collision determination unit 318 indicates that the possibility of collision is high, the control ECU 330 performs vehicle control to avoid collision and reduce damage by, for example, applying a brake, returning an accelerator, or suppressing engine output. The alert device 340 gives an alert to the user by sounding an alarm such as a sound, displaying alert information on a screen of a car navigation system or the like, giving vibration to a seat belt or a steering wheel, or the like.

In the present embodiment, an image of the surroundings of the vehicle, for example, the front or the rear is captured by the photoelectric conversion system 300. FIG. 21B illustrates the photoelectric conversion system in the case of capturing an image in front of the vehicle (imaging range 350). The vehicle information acquisition device 320 sends instructions to the photoelectric conversion system 300 or the imaging device 310. With such configuration, the accuracy of distance measurement may be further improved.

Although an example in which control is performed so as not to collide with another vehicle has been described above, the present disclosure is also applicable to control in which automatic driving is performed so as to follow another vehicle, control in which automatic driving is performed so as not to protrude from a lane, and the like. Further, the photoelectric conversion system is not limited to a vehicle such as an own vehicle, and may be applied to, for example, other movable objects (mobile devices), such as, for example, a ship, an aircraft, or an industrial robot. In addition, the present disclosure is not limited to the movable object and may be widely applied to equipment using object recognition, such as intelligent transport systems (ITS).

### Sixth Embodiment

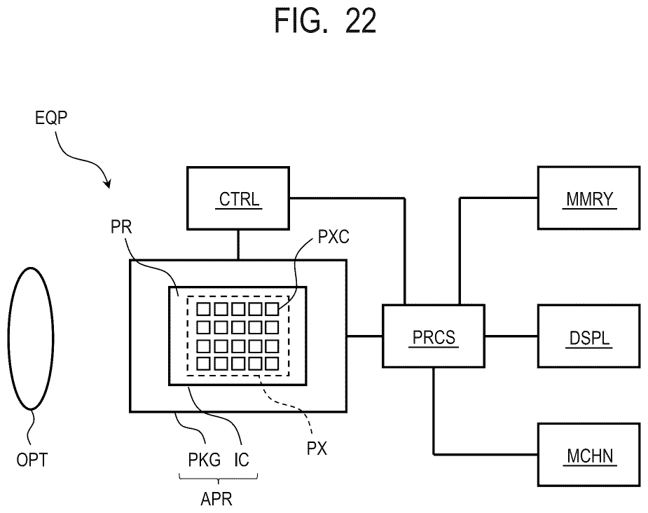

An equipment according to a sixth embodiment will be described with reference to FIG. 22. FIG. 22 is a block diagram illustrating a schematic configuration of an equipment according to the present embodiment.

FIG. 22 is a schematic diagram illustrating an equipment EQP including a photoelectric conversion device APR. The photoelectric conversion device APR has the function of the photoelectric conversion device 100 according to any one of the first to third embodiments. All or part of the photoelectric conversion device APR is a semiconductor device IC. The photoelectric conversion device APR of the present example may be used as, for example, an image sensor, an auto focus (AF) sensor, a photometric sensor, or a distance measurement sensor. The semiconductor device IC includes a pixel region PX in which pixel circuits PXC each including a photoelectric conversion unit are arranged in a matrix. The semiconductor device IC may include a peripheral region PR around the pixel region PX. A circuit other than the pixel circuit may be arranged in the peripheral region PR.

The photoelectric conversion device APR may have a structure (chip stacked structure) in which a first semiconductor chip provided with a plurality of photoelectric conversion units and a second semiconductor chip provided with peripheral circuits are stacked. Each of the peripheral circuits in the second semiconductor chip may be column circuits corresponding to pixel columns of the first semiconductor chip. The peripheral circuits in the second semiconductor chip may be matrix circuits corresponding to pixels or pixel blocks in the first semiconductor chip. As the connection between the first semiconductor chip and the second semiconductor chip, a through electrode (through silicon via (TSV)), an inter-chip wiring by direct bonding of a conductor such as copper, a connection by micro bumps between the chips, a connection by wire bonding, or the like may be employed.

The photoelectric conversion device APR may include a package PKG that accommodates the semiconductor device IC in addition to the semiconductor device IC. The package PKG may include a base body to which the semiconductor device IC is fixed, a lid body such as glass facing the semiconductor device IC, and connection members such as bonding wires or bumps for connecting terminals provided on the base body and terminals provided on the semiconductor device IC.

The equipment EQP may further include at least one of an optical device OPT, a control device CTRL, a processing device PRCS, a display device DSPL, a storage device MMRY, and a mechanical device MCHN. The optical device OPT corresponds to the photoelectric conversion device APR as a photoelectric conversion device, and is, for example, a lens, a shutter, or a mirror. The control device CTRL controls the photoelectric conversion device APR, and is, for example, a semiconductor device such as an ASIC. The processing device PRCS processes a signal output from the photoelectric conversion device APR and constitutes an analog front end (AFE) or a digital front end (DFE). The processing unit PRCS is a semiconductor device such as a central processing unit (CPU) or an ASIC. The display device DSPL may be an electroluminescent (EL) display device or a liquid crystal display (LCD) device that displays information (image) obtained by the photoelectric conversion device APR. The storage device MMRY may be a magnetic device or a semiconductor device that stores information (image) obtained by the photoelectric conversion device APR. The storage device MMRY may be a volatile memory such as an SRAM or a DRAM, or a nonvolatile memory such as a flash memory or a hard disk drive. The mechanical device MCHN may include a movable portion or a propulsion portion such as a motor or an engine. In the equipment EQP, a signal output from the photoelectric conversion device APR is displayed on the display device DSPL or transmitted to the outside by a communication device (not illustrated) included in the equipment EQP. Therefore, it is preferable that the equipment EQP further include a storage device MMRY and a processing device PRCS separately from the storage circuit unit and the arithmetic circuit unit included in the photoelectric conversion device APR.

The equipment EQP illustrated in FIG. 22 may be an electronic device such as an information terminal (for example, a smartphone or a wearable terminal) having a photographing function or a camera (for example, an interchangeable lens camera, a compact camera, a video camera, and a monitoring camera.). The mechanical device MCHN in the camera may drive components of the optical device OPT for zooming, focusing, and shutter operation. The equipment EQP may be a transportation device (movable object) such as a vehicle, a ship, or an airplane. The equipment EQP may be a medical device such as an endoscope or a CT scanner.

The mechanical device MCHN in the transportation device can be used as a mobile device. The equipment EQP as a transportation device is suitable for transporting the photoelectric conversion device APR, or for assisting and/or automating operation (manipulation) by an imaging function. The processing device PRCS for assisting and/or automating driving (manipulation) may perform processing for operating the mechanical device MCHN as a moving device based on information obtained by the photoelectric conversion device APR.

The photoelectric conversion device APR according to the present embodiment may provide a high value to a designer, a manufacturer, a seller, a purchaser, and/or a user thereof. Therefore, when the photoelectric conversion device APR is mounted on the equipment EQP, the value of the equipment EQP may also be increased. Therefore, in manufacturing and selling the equipment EQP, it is advantageous to determine the mounting of the photoelectric conversion device APR of the present embodiment on the equipment EQP in order to increase the value of the equipment EQP.

### Modified Embodiments

The present disclosure is not limited to the above embodiments, and various modifications are possible.

For example, an example in which a part of the configuration of any of the embodiments is added to another embodiment or an example in which a part of the configurations of any of the embodiments is substituted with some of the configurations of another embodiment is also an embodiment of the present disclosure.

Although the color filters of the RGB arrangement are described in the above embodiments, the color filters of the CMY arrangement including C pixels including a cyan color filter, M pixels including a magenta color filter, and Y pixels including a yellow color filter may be used. In addition to the color pixels of RGB, CMY, and the like, a pixel (white pixel) that directly detects incident light without color separation or an IR pixel including an infrared light transmission filter having a transmission wavelength region in an infrared wavelength region may be further included. In addition, in the above-described embodiments, an application example to a photoelectric conversion device that acquires a color image has been described, but the photoelectric conversion device does not necessarily need to be a photoelectric conversion device for acquiring a color image and may be applied to a photoelectric conversion device that acquires a monochrome image.

In the case of these pixel configurations, the pixel unit 10 may be considered to include a first pixel and a second pixel in each row. Here, the first pixel is the pixel 12 in which the charge of the photoelectric conversion unit PDA is transferred to the node FD by a first control signal, and the charge of the photoelectric conversion unit PDB is transferred to the node FD by a second control signal. The second pixel is the pixel 12 in which the charge of the photoelectric conversion unit PDA is transferred to the node FD by the second control signal, and the charge of the photoelectric conversion unit PDB is transferred to the node FD by the first control signal.

The first pixel and the second pixel may be pixels arranged adjacent in the row direction and having sensitivity to the same color. In the case of a monochrome sensor, the first pixel and the second pixel may be arranged in adjacent columns. When a plurality of first pixels and a plurality of second pixels are provided in each row, the first pixels and the second pixels may be alternately arranged in the row direction. The pixel unit 10 may further include a third pixel and a fourth pixel having sensitivity to a color different from that of the first pixel and the second pixel in each row. In this case, the first pixel, the third pixel, the second pixel, and the fourth pixel may be repeatedly arranged in this order in the row direction.

The photoelectric conversion systems described in the fourth and fifth embodiments are examples of photoelectric conversion systems to which the photoelectric conversion device of the present disclosure may be applied, and the photoelectric conversion system to which the photoelectric conversion device of the present disclosure may be applied is not limited to the configurations illustrated in FIG. 20 and FIG. 21A.

According to the present disclosure, it is possible to reduce the number of signals and the amount of signal processing by suppressing generation of a pair that cannot be compressed by addition in a photoelectric conversion device that performs a focus detection using a pupil division system on an imaging plane.

### Other Embodiments

Embodiment(s) of the present disclosure can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2024-199372, filed Nov. 15, 2024, which is hereby incorporated by reference herein in its entirety.

What is claimed is:

1. A photoelectric conversion device comprising:
a pixel unit including a plurality of pixels arranged to form a plurality of rows and a plurality of columns, each of the plurality of pixels including:
a first photoelectric conversion unit and a second photoelectric conversion unit that share one microlens;
a charge holding portion configured to hold charge transferred from the first photoelectric conversion unit and the second photoelectric conversion unit; and
an output unit configured to output a signal according to an amount of charge held by the charge holding portion;
a control unit configured to control a transfer of charge from first photoelectric conversion unit and the second photoelectric conversion unit to the charge holding portion in the plurality of pixels in unit of rows; and
a signal processing unit configured to process signals output from the pixel unit,
wherein the pixel unit includes, in each of the plurality of rows, a first pixel in which charge of the first photoelectric conversion unit is transferred to charge holding portion according to a first control signal and charge of the second photoelectric conversion unit is transferred to charge holding unit according to a second control signal, and a second pixel in which charge of the first photoelectric conversion unit is transferred to charge holding portion according to the second control signal and charge of the second photoelectric conversion unit is transferred to charge holding unit according to the first control signal,
wherein the control unit is configured to perform, for each of the plurality of rows, a first readout operation of supplying the first control signal and not supplying the second control signal, and a second readout operation of supplying the first control signal and the second control signal, and
wherein the signal processing unit is configured to output a first signal based on an amount of charge of the first photelectric conversion unit that is read out from the first pixel in accordance with the first readout operation and a second signal based on charges of the first photelectric conversion unit and the second photoelectric conversion unit that is read out from the first pixel in accordance with the second readout operation, and not to output a third signal based on an amount of charge of the second photoelectric conversion unit that is read out from the second pixel in accordance with the first readout operation.

2. The photoelectric conversion device according to claim 1,
wherein the signal processing unit includes a plurality of column analog-to-digital (AD) conversion units each provided corresponding to each of the plurality of columns and connected to the pixels of the corresponding column, and
wherein the signal processing unit is configured not to supply the third signal by stopping an AD conversion operation in a column AD conversion unit of a column in which the second pixel is arranged when performing a readout of the second pixel in accordance with the first readout operation.

3. The photoelectric conversion device according to claim 1, wherein the signal processing unit is configured to further output a fourth signal based on charges of the first photoelectric conversion unit and the second photoelectric conversion unit that is read out from the second pixel in accordance with the second readout operation.

4. The photoelectric conversion device according to claim 3, wherein the first signal is a phase difference detection signal, and the second signal and the fourth signal are image forming signals.

5. The photoelectric conversion device according to claim 1, wherein the signal processing unit is configured to acquire the third signal and a fourth signal based on charges of the first photoelectric conversion unit and the second photoelectric conversion unit that is read out from the second pixel in accordance with the second readout operation and generate a fifth signal by subtracting the third signal from the fourth signal.

6. The photoelectric conversion device according to claim 5,
wherein the signal processing unit includes a first memory configured to hold the first signal, a second memory configured to hold the second signal, a third memory configured to hold the third signal, and a fourth memory configured to hold the fourth signal,
wherein the signal processing unit is configured to parallelly output the first signal read out from the first memory and the fifth signal obtained by subtracting the third signal read out from the third memory from the fourth signal read out from the fourth memory, and
wherein the signal processing unit is configured to parallelly output the second signal read out from the second memory and the fourth signal read out from the fourth memory.

7. The photoelectric conversion device according to claim 6, wherein the first memory, the second memory, the third memory, and the fourth memory constitute a line memory.

8. The photoelectric conversion device according to claim 6, wherein the first memory, the second memory, the third memory, and the fourth memory are configured by a frame memory.

9. The photoelectric conversion device according to claim 5, wherein the first signal and the fifth signal are phase difference detection signals, and the second signal and the fourth signal are image forming signals.

10. The photoelectric conversion device according to claim 5, wherein the signal processing unit is configured to output a sixth signal obtained by adding the first signal and the fifth signal and a seventh signal obtained by adding the second signal and the fourth signal.

11. The photoelectric conversion device according to claim 10, wherein the sixth signal is a phase difference detection signal, and the seventh signal is an image forming signal.

12. A photoelectric conversion device comprising:
a pixel unit including a plurality of pixels arranged to form a plurality of rows and a plurality of columns, each of the plurality of pixels including:
a first photoelectric conversion unit and a second photoelectric conversion unit that share one microlens;
a charge holding portion configured to hold charge transferred from the first photoelectric conversion unit and the second photoelectric conversion unit; and
an output unit configured to output a signal according to an amount of charge held by the charge holding portion;
a control unit configured to control a transfer of charge from first photoelectric conversion unit and the second photoelectric conversion unit to the charge holding portion in the plurality of pixels in unit of rows; and
a signal processing unit configured to process signals output from the pixel unit,
wherein the pixel unit includes, in each of the plurality of rows, a first pixel in which charge of the first photoelectric conversion unit is transferred to charge holding portion according to a first control signal and charge of the second photoelectric conversion unit is transferred to charge holding unit according to a second control signal, and a second pixel in which charge of the first photoelectric conversion unit is transferred to charge holding portion according to the second control signal and charge of the second photoelectric conversion unit is transferred to charge holding unit according to the first control signal,
wherein the signal processing unit includes a signal addition unit configured to add a signal read out from the first pixel and a signal read out from the second pixel,
wherein the control unit is configured to perform, for each of the plurality of rows, a first readout operation of supplying the first control signal and not supplying the second control signal, and
wherein the signal processing unit is configured to output a first signal based on an amount of charge of the first photelectric conversion unit that is read out from the first pixel in accordance with the first readout operation and an eighth signal obtained by adding the first signal and a third signal based on an amount of charge of the second photoelectric conversion unit read out from the second pixel in accordance with the first readout operation, and not to output the third pixel.

13. The photoelectric conversion device according to claim 12, wherein the signal processing unit is configured to output the first signal and the eighth signal in parallel.

14. The photoelectric conversion device according to claim 13, wherein the first signal is a phase difference detection signal, and the eighth signal is an image forming signal.

15. The photoelectric conversion device according to claim 12,
wherein, in a first frame, the signal processing unit is configured to output the first signal and the eighth signal, and not to output the third signal, and
wherein, in a second frame different from the first frame, the control unit is configured to perform, for each of the plurality of rows, the first readout operation and a second readout operation of supplying the first control signal and the second control signal, and the signal processing unit is configured to output the first signal and a second signal based on charges of the first photoelectric conversion unit and the second photoelectric conversion unit read out from the first pixel in accordance with the second readout operation, and not to output the third signal.

16. The photoelectric conversion device according to claim 1, wherein the first pixel and the second pixel are pixels having sensitivity to the same color.

17. The photoelectric conversion device according to claim 1, wherein the pixel unit includes a plurality of the first pixels and a plurality of the second pixels in each of the plurality of rows, and the first pixels and the second pixels are alternately arranged in a row direction.

18. The photoelectric conversion device according to claim 17,
wherein the pixel unit further includes a plurality of third pixels and a plurality of fourth pixels having sensitivity to a color different from that of the first pixel and the second pixel, and
wherein the first pixel, the third pixel, the second pixel, and the fourth pixel are repeatedly arranged in this order in the row direction.

19. The photoelectric conversion device according to claim 1, wherein the microlens is configured to allow light incident on a first pupil region of an optical system that forms an image on the pixel unit to be incident on the first photoelectric conversion unit and allow light incident on a second pupil region different from the first pupil region of the optical system to be incident on the second photoelectric conversion unit.

20. The photoelectric conversion device according to claim 1, wherein the control unit is configured to simultaneously drive two or more rows in which the first pixel and the second pixel are arranged in the same column.

21. A photoelectric conversion system comprising:
the photoelectric conversion device according to claim 1; and
a signal processing device configured to process a signal output from the photoelectric conversion device.

22. A movable object comprising:
the photoelectric conversion device according to claim 1;
a distance information acquisition unit configured to acquire distance information to an object from a parallax image based on a signal from the photoelectric conversion device; and
a control unit configured to control the movable object based on the distance information.

23. An equipment comprising:
the photoelectric conversion device according to claim 1; and
at least one of
an optical device corresponding to the photoelectric conversion device,
a control device configured to control the photoelectric conversion device,
a processing device configured to process a signal output from the photoelectric conversion device,
a mechanical device that is controlled based on information obtained by the photoelectric conversion device,
a display device configured to display information obtained by the photoelectric conversion device, and
a storage device configured to store information obtained by the photoelectric conversion device.
